(19) United States
(12) Patent Application Publication
(10) Pub. No.: US 2026/0331185 A1
(43) Pub. Date: Oct. 22, 2026

(54) SYSTEMS AND METHODS FOR IN-MEMORY COMPUTING AND ANALOG PROCESSING IN NAND-BASED MEMORY

(71) Applicant: Mythic, Inc., Round Rock, TX (US)

(72) Inventors: Laura Fick, Hutto, TX (US); Dave Fick, Hutto, TX (US); Jonathan Huynh, San Jose, CA (US)

(73) Assignee: Mythic, Inc., Round Rock, TX (US)

(21) Appl. No.: 19/566,052

(22) Filed: Mar. 13, 2026

Related U.S. Application Data
(60) Provisional application No. 63/890,567, filed on Sep. 30, 2025.
(60) Provisional application No. 63/778,380, filed on Mar. 26, 2025.

(51) Int. Cl. G11C 16/26; G06F 7/544; G11C 16/24; G11C 16/32; G11C 16/34

(52) U.S. Cl. CPC G11C 16/26; G06F 7/5443; G11C 16/24; G11C 16/32; G11C 16/34

(57) ABSTRACT

An integrated circuit includes an analog compute accelerator having a plurality of conductive lines and a plurality of programmable memory elements. A configurable selection network is configured to select a subset of the plurality of conductive lines to define a selectable compute region of the analog compute accelerator. An analog readout circuit is coupled to the analog compute accelerator and is configured to accumulate electrical contributions generated by the programmable memory elements in response to applied input activation signals. An analog-to-digital converter is configured to convert an accumulated analog value produced by the analog readout circuit into a digital output value. The integrated circuit enables in-memory analog computation by selectively activating programmable memory elements within the selectable compute region and accumulating resulting electrical contributions to produce a weighted analog result for conversion into the digital output value.

### CROSS-REFERENCE TO RELATED APPLICATIONS

This application claims the benefit of US Provisional Application number 63/778,380, filed 26-MAR-2025, and US Provisional Application number 63/890,567, filed 30-SEP-2025, which are incorporated in their entireties by this reference.

### TECHNICAL FIELD

The present application relates to integrated circuit architecture, specifically to in-memory computing and analog processing systems for executing machine learning algorithms and models, such as large language models (LLMs), as well as other forms of artificial intelligence (AI) models, signal processing applications, and advanced computational tasks in NAND flash memory for low-power edge computing applications.

### BACKGROUND

In recent years, the deployment of AI models, including large language models (LLMs), has increasingly extended from cloud computing environments to edge computing devices, driven by the need for real-time processing, reduced latency, and energy efficiency. Traditional digital circuitry used in implementing these language models requires memory resources, high power consumption, and often leads to increased latency, particularly when performing intensive tasks such as natural language processing (NLP) and machine learning inference.

NAND (Not-AND) flash memory, widely recognized for its cost-effectiveness and storage density, presents a potential alternative to traditional DRAM for edge applications. However, the inherent latency and slower read/write speeds of NAND flash memory have limited its application in high-performance computing tasks. To overcome these challenges, innovative approaches that integrate in-memory computing with analog processing directly within NAND flash arrays may be described by one or more embodiments of the present application. These approaches aim to reduce data transfer bottlenecks, minimize power consumption, and enable efficient execution of inference tasks of AI models being implemented at edge and/or user devices.

The embodiments of the present application address these challenges by introducing a novel system and method for performing AI inference tasks directly within NAND flash memory using analog computing techniques. The systems and methods may be designed to support low-power, high-efficiency deployment of LLMs in edge devices, enabling advanced AI functionalities in resource-constrained environments.

### BRIEF SUMMARY OF THE EMBODIMENTS

In one embodiment, an integrated circuit includes an analog compute accelerator comprising a plurality of conductive lines and a plurality of programmable memory elements, a configurable selection network configured to select a subset of the plurality of conductive lines to define a selectable compute region of the analog compute accelerator, an analog readout circuit coupled to the analog compute accelerator and configured to accumulate electrical contributions generated by the programmable memory elements in response to applied input activation signals, and an analog-to-digital converter configured to convert an accumulated analog value produced by the analog readout circuit into a digital output value.

In one embodiment, the analog compute accelerator comprises a NAND flash memory array.

In one embodiment, the plurality of conductive lines comprises a plurality of bitlines arranged to intersect with a plurality of wordlines to form a grid of memory cells.

In one embodiment, the plurality of conductive lines further comprises a plurality of select gate lines operably coupled to memory cells of the analog compute accelerator.

In one embodiment, the plurality of conductive lines are arranged such that each conductive line of a first set intersects with a plurality of conductive lines of a second set to form programmable memory cell locations within the analog compute accelerator.

In one embodiment, the configurable selection network is configured to form one or more banks comprising a selectable grouping of conductive lines.

In one embodiment, the one or more banks comprise one or more of a bitline bank, a wordline bank, or a select-gate bank.

In one embodiment, the configurable selection network comprises a bitline multiplexer configured to form a bitline bank coupled to a shared integration node of the analog readout circuit.

In one embodiment, the analog readout circuit comprises an integrating analog front-end circuit configured to perform charge summation of analog signals produced by the programmable memory elements.

In one embodiment, the integrated circuit further includes a pulse width modulation circuit configured to encode input activation signals as pulse-width modulated signals applied to select-gate lines of the analog compute accelerator.

In one embodiment, input activation signals are encoded as a plurality of binary input bits sequentially applied to select-gate lines of the analog compute accelerator.

In one embodiment, the analog readout circuit is configured to perform signed arithmetic using differential bitlines.

In one embodiment, the analog readout circuit is configured to perform signed arithmetic using time-multiplexed positive and negative input signals applied over sequential time intervals.

In one embodiment, the integrated circuit further includes one or more calibration circuits configured to program threshold voltages of the programmable memory elements using common digital-to-analog converter voltages.

In one embodiment, the integrated circuit is implemented within a system-in-package architecture comprising a plurality of semiconductor dies coupled using micro-bump interconnect structures.

In one embodiment, the integrated circuit is implemented within a wafer-level stacked architecture comprising a NAND wafer, a digital processing wafer, and a dynamic random-access memory wafer coupled using through-silicon vias.

In one embodiment, a method for performing analog in-memory computation within an integrated circuit includes configuring an analog compute accelerator comprising a plurality of conductive lines and a plurality of programmable memory elements, selecting, using a configurable selection network, a subset of the plurality of conductive lines to define a selectable compute region of the analog compute accelerator, applying input activation signals to the selectable compute region, generating electrical contributions corresponding to stored weight values of the programmable memory elements and the applied input activation signals, accumulating the electrical contributions using an analog readout circuit to produce an accumulated analog value representing a weighted sum associated with an analog computation operation, and converting the accumulated analog value into a digital output value using an analog-to-digital converter.

In one embodiment, selecting the subset of the plurality of conductive lines includes forming a bank comprising a selectable grouping of the plurality of conductive lines.

In one embodiment, an integrated circuit includes a NAND flash memory matrix comprising a plurality of bitlines and a plurality of wordlines forming a grid of memory cells and a plurality of select gate devices operably coupled to the memory cells, a pulse width modulation circuit configured to generate a plurality of pulse-width modulated signals based on digital input values, each pulse-width modulated signal having a width corresponding to a respective amplitude of the digital input value, a plurality of analog input driver circuits configured to apply the pulse-width modulated signals to one or more select gate devices of the NAND flash memory matrix, one or more analog front-end circuits coupled to the NAND flash memory matrix and configured to receive analog output signals from a subset of the memory cells activated by the pulse-width modulated signals and integrate the analog output signals over a defined integration window to generate an accumulated analog signal representing a weighted summation of stored values in the subset, one or more analog-to-digital converters configured to convert the accumulated analog signal into a digital output value, and a control circuit configured to sequentially apply a plurality of binary input bits to the select gate devices and direct the analog front-end circuit to perform a binary-weighted summation by accumulating charge corresponding to each bit of the plurality of binary input bits.

In one embodiment, the control circuit is configured to apply the plurality of binary input bits to the select gate devices during respective sequential time intervals corresponding to binary weight values, and the analog front-end circuit accumulates charge generated during each respective time interval such that the accumulated analog signal represents a binary-weighted sum corresponding to a multiply-accumulate operation between the plurality of binary input bits and stored values of the memory cells.

### BRIEF DESCRIPTION OF THE FIGURES

FIG. 1 is an example schematic of a NAND flash block with a wordline bank select, in accordance with one or more embodiments of the present application;

FIG. 2 illustrates a method 200 for implementing in-memory computations using NAND flash memory in accordance with one or more embodiments of the present application;

FIG. 3 is an example schematic of a NAND flash block, in accordance with one or more embodiments of the present application;

FIG. 4 is an example schematic of a NAND flash block with an analog front-end (AFE) and an analog-to-digital converter (ADC), in accordance with one or more embodiments of the present application;

FIG. 5 is an example schematic of a NAND flash block with a single-ended AFE and bitline multiplexer, in accordance with one or more embodiments of the present application;

FIG. 6 is an example schematic of a NAND flash block with a plurality of analog input digital-to-analog converters (DACs), in accordance with one or more embodiments of the present application;

FIG. 7 is an example schematic of a NAND flash block with a non-integrating AFE, in accordance with one or more embodiments of the present application;

FIG. 8 is an example schematic of a NAND flash block with an integrating AFE and wordline bank select, in accordance with one or more embodiments of the present application;

FIG. 9 is an example schematic of a NAND flash block with an analog input DAC and wordline bank select, in accordance with one or more embodiments of the present application;

FIG. 10 is an example schematic of NAND flash block for multiplicative inputs with AFE charge summation, in accordance with one or more embodiments of the present application;

FIG. 11 is an example system-level architecture of an analog compute system-in-package including host interface, digital processing unit, DRAM buffer, and NAND/analog compute die, in accordance with one or more embodiments of the present application;

FIG. 12 is an example chip-level system-in-package architecture using micro-bump interconnects between NAND/analog, DRAM, and digital dies, in accordance with one or more embodiments of the present application;

FIG. 13 is an example wafer-level stacked architecture including a NAND wafer, a digital wafer, and a DRAM wafer vertically integrated using through-silicon vias;

FIG. 14 is an example planar interposer-based multi-die architecture including NAND/analog, DRAM, and digital wafers disposed along a common plane and electrically coupled through an interposer or substrate;

FIG. 15 is an example schematic of a NAND flash memory block including select gate source (SGS) devices and a source line coupled to NAND memory cell strings, in accordance with one or more embodiments of the present application; and

FIG. 16 is an example schematic of a NAND flash memory block including select gate source (SGS) devices configured to selectively couple NAND memory cell strings to a reference potential through a source line, in accordance with one or more embodiments of the present application.

### DESCRIPTION OF THE PREFERRED EMBODIMENTS

The following description of the preferred embodiments of the present application is not intended to limit the inventive concepts of the present application to these preferred embodiments, but rather to enable any person skilled in the art to make and use the embodiments of the present application.

### Overview

The present application provides a novel system and method for executing machine learning models including neural networks, transformer models, and large language models (LLMs) in computing environments, including but not limited to edge computing environments, using in-memory computing and analog processing within NAND flash memory. The embodiments of the present application may be designed to overcome the limitations of traditional digital circuitry, which often requires substantial memory resources and consumes power, resulting in higher latency and inefficiency in resource-constrained environments.

Embodiments of the present application leverage the inherent advantages of NAND flash memory, integrating analog processing techniques directly within the memory arrays to perform AI inference tasks. By reducing data transfer bottlenecks and minimizing power consumption, this system enables efficient execution of AI models, particularly LLMs, in low-power edge devices such as IoT devices, mobile platforms, and other consumer electronics. The scalable architecture of the system allows for the deployment of multiple AI models within a single device, optimizing both performance and energy usage.

This innovative approach not only enhances the capability of edge devices to perform complex AI tasks but also reduces the hardware footprint and energy consumption, making it suitable for a wide range of applications in environments where traditional high-power computing resources may be not feasible.

### Technical Benefits

Embodiments of the present application provide advancement in the domain of in-memory computing by implementing NAND flash memory for large-scale matrix multiplication, required for AI inference engines, particularly in executing operations for Large Language Models (LLMs). Traditional NAND flash architectures may be limited by their inability to handle simultaneous multi-cell read operations efficiently, which constrains their application in high-performance neural network computations. The embodiments of the present application overcome such limitations by employing a novel combination of pulse-width modulated inputs and integrating analog front-ends, enabling the concurrent activation of multiple memory cells across bit lines and select gates thereby allowing for the summation of electrical currents over configurable cycles, effectively performing matrix multiplications directly within the NAND memory array.

In one or more embodiments, an integration of differential and single-ended analog front-ends enables flexibility in handling both positive and negative weights, streamlining the process of matrix multiplication and subtraction. By circumventing the need for traditional digital computation methods, this technical approach reduces the readout time and energy consumption associated with large-scale neural network operations. Additionally, or alternatively, a use of pulse-width modulation facilitates precise control over the duration of cell activation, optimizing the efficiency of current summation in the analog domain. This method not only enhances the computational throughput but also minimizes the latency typically encountered in digital processing frameworks.

Additionally, or alternatively, the architecture(s) in various embodiments of the present application may be designed to be scalable, accommodating high-density NAND flash arrays with increased numbers of select gates and reduced bit line counts, tailored to the specific input sizes and weight multiplications that may be required for complex neural networks. This configuration maximizes the utilization of available memory resources, ensuring that the compute system can handle substantial datasets and extensive computations with reduced physical space and power requirements. An ability to modify the front-end amplifier design to suit specific input configurations further extends the versatility of the embodiments of the present application, allowing the NAND-based integrated circuit to adapt to varying computational demands without compromising speed or accuracy.

Accordingly, the various embodiments of the present application enable an application of NAND flash technology for AI computations, offering a cost-effective, high-performance solution that addresses the inherent limitations of existing memory architectures in handling the growing demands of AI processing tasks, such as natural language processing utilizing LLMs and real-time data analytics.

### System for NAND-Based In-Memory Analog Computations

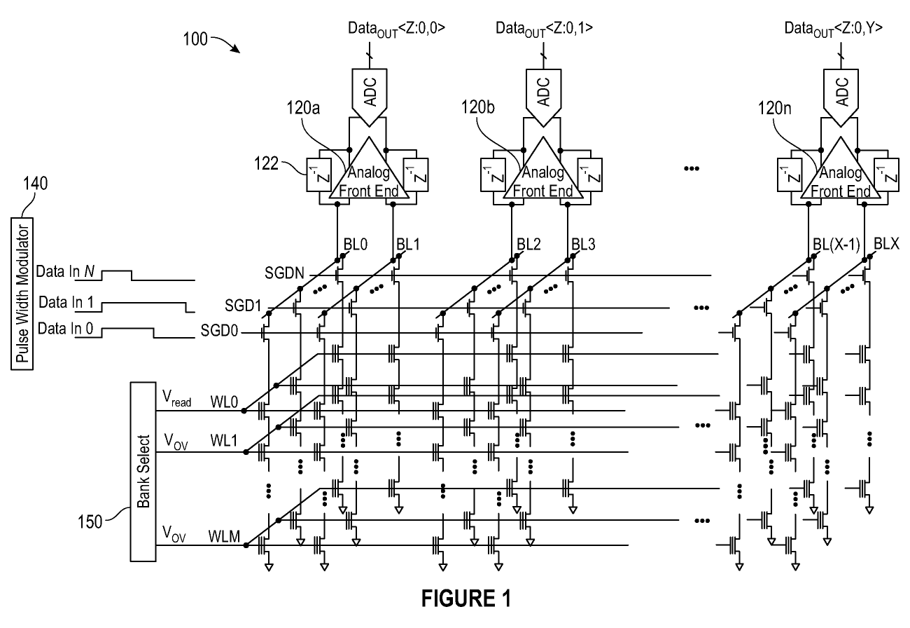

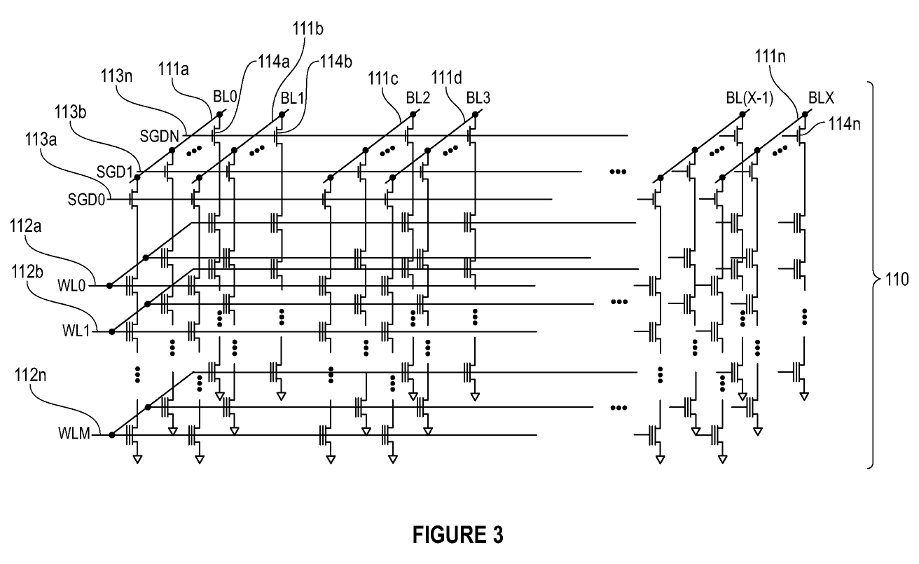

As shown in FIG. 1, a system 100 for implanting NAND-based in memory analog computation includes NAND flash memory matrix 110, one or more analog front ends 120a-120n, a pulse width modulator 140, and a worldline bank select 150. Additionally, or alternatively, as shown in FIGS. 3-9, variations of the system 100 may further includes one or more analog- to- digital converters (ADCs) 130a- 130n, select gate bank select 155, bit line multiplexer 165, analog input digital-to-analog (DAC) converters 170, and analog input DAC 180.

### 1.10 NAND Flash Memory Matrix

In one or more embodiments, NAND flash memory matrix 110, which is sometimes referred to herein as NAND flash block, preferably functions as a memory store for weights and/or biases of an artificial neural network or other computationally dense algorithm. Additionally, NAND flash memory matrix 110 preferably functions to enable in-memory computations, such as matrix multiplication, in the analog domain based on a dot product of analog neuron weights and analog input activations.

In one or more embodiments, NAND flash memory matrix 110 comprises a plurality of bitlines 111a through 111n, where "n" represents any letter. In such embodiments, each bitline of the plurality of bitlines 111athrough 111nmay be configured to intersect with a plurality of wordlines 112athrough 112n, as shown by way of example in FIG. 3. The intersection of the plurality of bitlines 111a through 111n and the plurality of wordlines 112athrough 112nform a plurality of grid arrangements within NAND flash memory matrix 110 thereby creating a plurality of memory cells or programmable memory elements. Each memory cell of the plurality of memory cells, at the intersection of a given bitline of the plurality of bitlines 111 and a given wordline of the plurality of wordlines 112a through 112n, may be configured and/or programmed to store data through multi-level cell technology, utilizing different threshold voltage levels within the memory cell to enhance storage capacity. As used herein, a “programmable memory element” may refer to a memory device having a programmable electrical characteristic, including threshold voltage, resistance, conductance, or charge state, that represents a stored value usable in analog computation. As non-limiting examples, programmable memory elements may comprise flash memory cells, floating gate transistors, charge trap memory cells, resistive memory cells, phase-change memory cells, ferroelectric memory cells, or other programmable memory devices

Additionally, or alternatively, NAND flash memory matrix 110 includes a plurality of select gates 113athrough 113n. In one or more embodiments, each select gate of the plurality of select gates 113athrough 113nmay function as an access controller, via a select gate line or the like, providing selective control over the activation and deactivation of specific rows of devices (e.g., resistors or the like) within NAND flash memory matrix 110. Each select gate of the plurality of select gates 113athrough 113n may be connected to a series of memory cells of NAND flash memory matrix 110 therefore enabling each respective select gate access control for isolating or activating rows of devices for computations, read or write operations. A “select gate line” may refer to a control line coupled to one or more select gate transistors that control access to one or more strings of memory cells within a NAND flash architecture.

In some embodiments, the plurality of select gates 113athrough 113nmay function through the use of transistor switches connectedly aligned with rows of NAND flash memory matrix 110. As discussed above, the alignment of the plurality of select gates 113a, in this manner, enables each select gate to facilitate or inhibit data flow by controlling electrical signals to designated rows of NAND flash memory matrix 110. Accordingly, an operation of the plurality of select gates 113a determines which memory cells of NAND flash memory matrix 110 may be operational for computation operation, read or write functions, thereby determining pathways for data and computational signals.

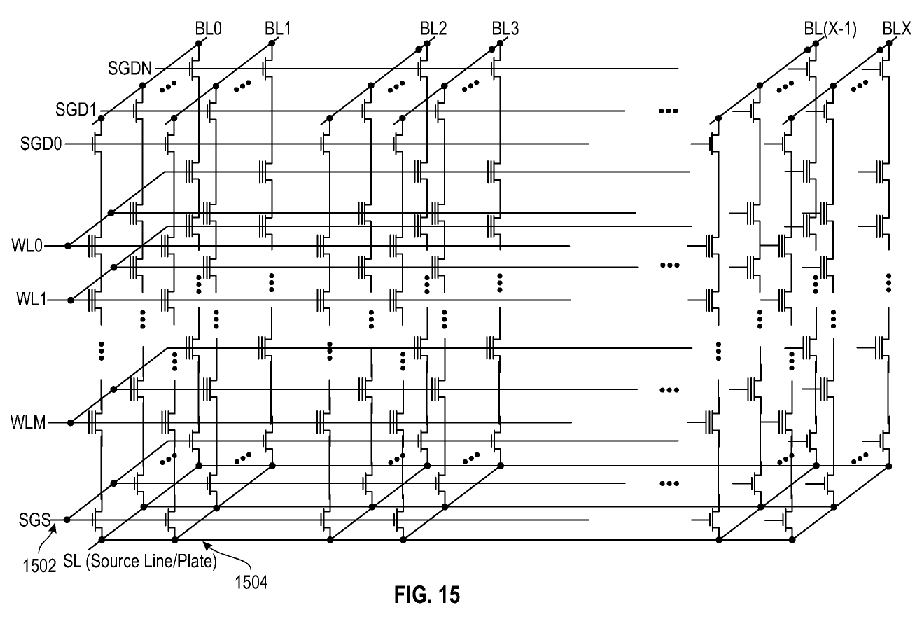

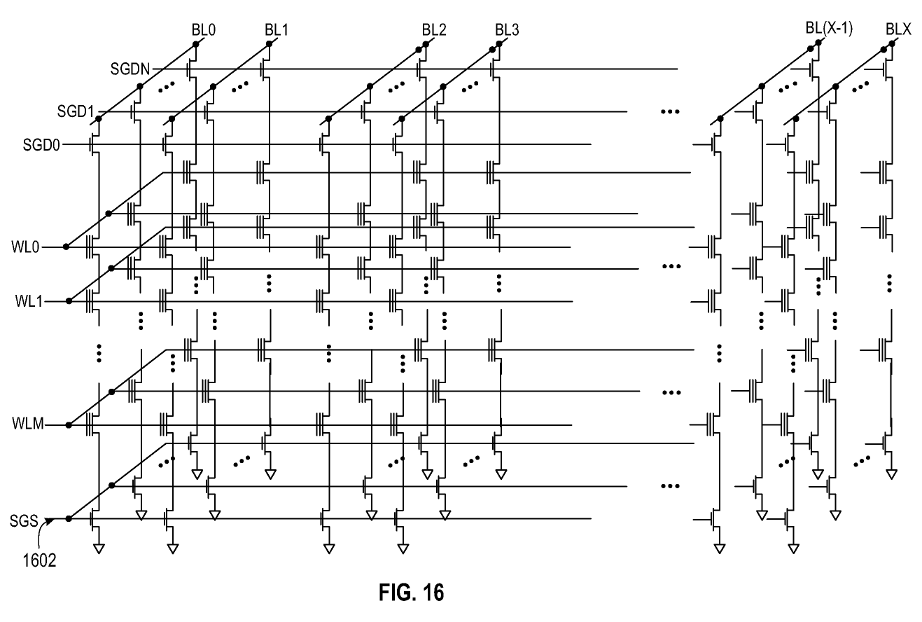

In one or more embodiments, the NAND flash memory matrix may further include select gate source devices positioned between lower ends of NAND strings and a common source line. The select gate source devices may function to selectively connect or isolate one or more NAND strings from the source line during read, write, or analog computation operations. Additional structural examples of the select gate source devices and source line connections are illustrated in FIGS. 15 and 16.

In one or more embodiments, FIGS. 15 and 16 illustrate additional structural details of a NAND flash memory block that may be used within NAND flash memory matrix 110. In particular, FIGS. 15 and 16 illustrate implementations of the NAND string architecture including select gate devices positioned at both ends of a string of memory cells. In such embodiments, the NAND flash block may include a plurality of bitlines, a plurality of wordlines forming layers of memory cells, one or more select gate devices positioned between the bitlines and the memory cell strings, and one or more select gate source devices positioned between the memory cell strings and a common source line. The common source line may also be referred to as a source plate or cell source and may provide a shared electrical reference for the memory cell strings within a NAND flash block. The inclusion of select gate source devices allows portions of the NAND flash array to be selectively enabled or disabled during read, inference, or analog computation operations described throughout the present application. In some embodiments, the NAND flash block structure illustrated in FIGS. 15 and 16 may be implemented in either a two-dimensional NAND architecture or a three-dimensional NAND architecture including vertically stacked layers of memory cells.

In one or more embodiments, FIG. 15 illustrates an expanded schematic representation of a NAND flash memory block architecture that includes select gate source devices and a common source line. In such embodiments, the NAND flash memory block may include a plurality of bitlines BL0 through BLX, a plurality of wordlines WL0 through WLM forming layers of memory cells, and a plurality of select gate devices SGD0 through SGDN positioned between the bitlines and the strings of memory cells. In addition to the select gate devices associated with the bitlines, the NAND flash memory block may further include one or more select gate source devices 1502 coupled between lower ends of the memory cell strings and a common source line 1504. The common source line 1504 may also be referred to as a source plate or cell source and may provide a shared electrical connection for the memory cell strings within a NAND flash block.

In some embodiments, the select gate source devices 1502 may function to electrically couple or decouple groups of memory cell strings to the common source line 1504 during operation of the memory array. Activation of select gate source devices 1502 may enable conduction paths through the memory cell strings during read, inference, or computation operations performed within the analog compute accelerator. Conversely, deactivation of select gate source devices 1502 may electrically isolate the memory cell strings from the source line, thereby disabling corresponding portions of the memory array. Through operation of the select gate source devices 1502, the NAND flash memory architecture may divide the memory array into multiple independently controllable blocks, where a selected block may be enabled while other blocks remain electrically isolated.

In embodiments of the present application, the select gate source devices 1502 may operate in coordination with the select gate devices SGD0 through SGDN and the wordlines WL0 through WLM to enable controlled activation of memory cell strings for analog computation operations. For example, enabling select gate devices and select gate source devices may allow one or more memory cell strings to conduct currents corresponding to stored weight values when input activation signals are applied. Electrical contributions produced by activated memory cells may then propagate through the bitlines BL0 through BLX toward associated analog front-end circuits. In certain embodiments, enabling select gate source devices 1502 may allow multiple strings to be activated simultaneously through corresponding select gate devices, thereby supporting parallel analog accumulation operations across selected portions of the memory array.

The NAND flash block architecture illustrated in FIG. 15 may be implemented in a two-dimensional NAND flash structure or a three-dimensional NAND flash structure comprising vertically stacked layers of memory cells. In some implementations, multiple NAND flash blocks may be tiled together to form one or more planes of memory within an integrated circuit. A memory device may further include multiple planes arranged within a single die, thereby providing scalable storage capacity and computational resources for the analog compute accelerator.

Additionally, or alternatively, in some embodiments, multiple select gate source devices within a block may be electrically tied together and controlled by a common control signal.

In one or more embodiments, FIG. 16 illustrates a variation of the NAND flash memory block architecture including select gate source devices and a source line connection configured for operation relative to a reference potential such as ground. Similar to the architecture described with reference to FIG. 15, the NAND flash block may include a plurality of bitlines BL0 through BLX, a plurality of wordlines WL0 through WLM defining layers of memory cells, and a plurality of select gate devices SGD0 through SGDN positioned along upper ends of the NAND strings. The NAND strings may extend vertically or horizontally depending on whether the memory array is implemented using a two-dimensional NAND structure or a three-dimensional NAND structure.

In the embodiment of FIG. 16, one or more select gate source devices 1602 may be positioned between lower ends of the NAND strings and a source line that may be coupled to a reference potential such as ground (VSS). The source line may function as a common return path for currents flowing through the NAND strings during read, inference, or computation operations. In such embodiments, activation of select gate source devices 1602 may electrically connect corresponding NAND strings to the source line, thereby enabling current flow through memory cells associated with the activated strings. Deactivation of the select gate source devices 1602 may electrically isolate the NAND strings from the source line, preventing current flow and disabling the corresponding portion of the memory array.

In one or more embodiments, the select gate source devices 1602 may function as block enable switches that allow selected NAND flash blocks to participate in read or analog computation operations while other blocks remain disabled. For example, during analog in-memory computation operations described throughout the present application, enabling the select gate source devices 1602 may allow currents generated by memory cells in response to applied input activation signals to propagate through the NAND strings toward associated bitlines. The resulting current signals may then be sensed and accumulated by analog front-end circuitry coupled to the bitlines.

In certain implementations, multiple select gate source devices may exist within a NAND flash block due to layered NAND structures used in three-dimensional NAND flash memory. In some embodiments, multiple select gate source devices may be electrically coupled together and controlled using a common control signal so that the plurality of select gate source devices operate collectively to enable or disable conduction through the NAND strings of a given block. Such configuration may simplify control circuitry and allow efficient block-level activation during read or analog computation operations.

In one or more embodiments, the NAND flash architecture illustrated in FIG. 16 may be tiled across multiple blocks to form a plane of memory, and multiple planes may be integrated within a single semiconductor die. The inclusion of select gate source devices and the common source line structure may therefore enable scalable block-level control of NAND memory arrays while supporting parallel activation of selected memory cell strings during analog in-memory computation operations.

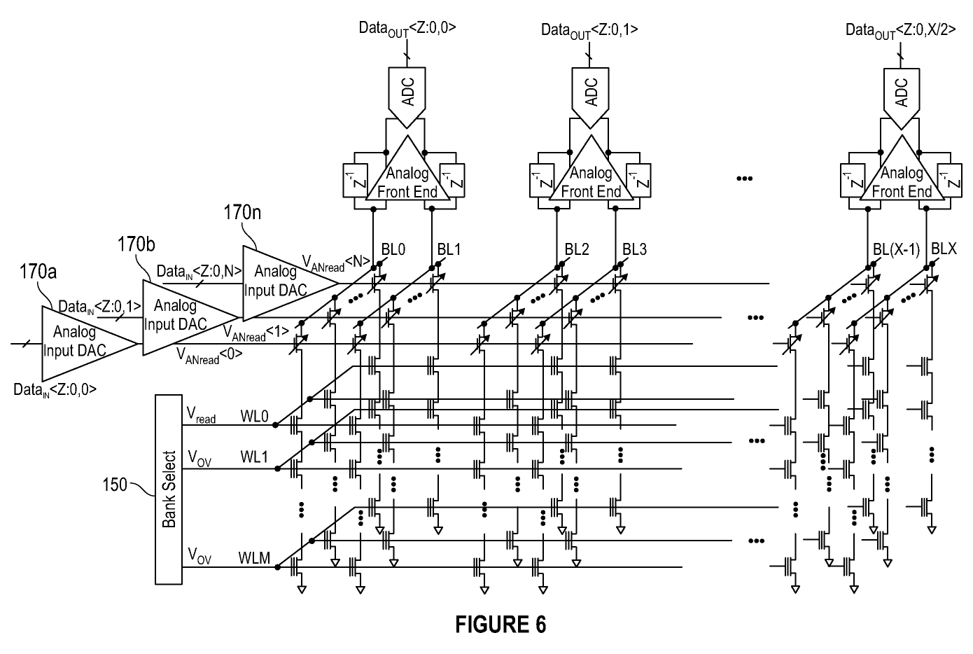

In one or more additional embodiments, and as illustrated in FIG. 6, each select gate of the plurality of select gates 113athrough 113nis further configured to receive analog voltage inputs from analog input digital-to-analog converters (DACs) 170. In such embodiments, each select gate functions not only as a binary access switch but also as a controllable analog element whose gate voltage modulates the channel conductance. As such, the analog modulation enables the select gates to participate in analog in-memory computation by scaling the current contribution from the associated memory cells during dot-product or matrix-vector operations. The application of analog voltages to the select gates allows for fine-grained control over the effective signal path, thereby enabling the select gates to function as analog input nodes for weighted computation based on signal amplitude, pulse width, or other analog coding techniques.

Accordingly, the gating function of the plurality of select gates 113a through 113nensures that only a subset of memory cells undergoing signal processing during computational operations may be read by downstream readout devices, such as an analog front-end couple to an ADC or the like, thereby enabling variable mappings of neural network weights and optimizing power usage and enhancing system efficiency.

Additionally, or alternatively, NAND flash memory matrix 110 may be implemented in both two-dimensional (2D) and three-dimensional (3D) configurations. In one or more embodiments, the 2D configuration of NAND flash memory matrix 110 involves stacking a plurality of wordlines and a plurality of bitlines within a single plane (i.e., a layer), creating a flat grid where in-memory computation operations may be performed.

In some implementations, the 3D configuration of NAND flash memory matrix 110 includes vertical stacking of multiple 2D planes or layers composed of a combination of wordlines and bitlines. The 3D configuration of NAND flash memory matrix 110 may function to increase the storage density by expanding the memory capacity vertically, thus effectively utilizing three-dimensional space. The 3D arrangement of NAND flash memory matrix 110 allows for higher scalability, accommodating a greater number of bitlines 111a through 111nand wordlines 112athrough 112nwhile maintaining a compact circuit footprint. In one or more embodiments, the vertical stacking of layers of bitlines and wordlines facilitates more complex data operations, as data may traverse through multiple planes or layers of NAND flash memory matrix 110 during computational processes thereby leveraging the advantages of three-dimensional integration.

### 1.20 Integrating Analog Front-End Circuit

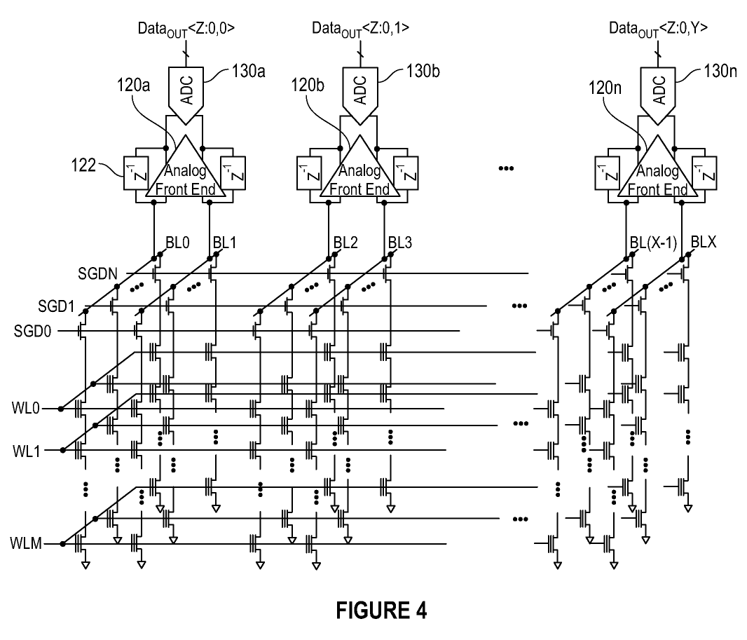

As shown in FIG. 4, in one or more embodiments, integrating analog front-end circuits 120a through 120noperably interface with NAND flash memory matrix 110 to enable a readout of the analog signals from NAND flash memory matrix 110 to enable an eventual conversion of the analog signals to digital signals. Integrating analog front-end circuit 120athrough 120npreferably function to receive analog signals generated from in-memory computations within NAND flash memory matrix 110. In such embodiments, the in-memory computations, typically involve dot products or matrix multiplies of analog neuron weights matrices and analog input activations matrices.

Integrating analog front-end circuits 120athrough 120n may function to perform analog signal integration, receiving the analog outputs from the various, bitline banks, and/or rows and columns formed by bitlines 111athrough 111nand wordlines 112athrough 112nof NAND flash memory matrix 110. In one or more embodiments, the signal integration performed by integrating analog front-end circuits 120athrough 120n may be accomplished through a series of interconnected operational amplifiers and filters designed to manage combined electrical signals, effectively accumulating and preparing these analog signals for subsequent conversion by an analog-to-digital converter.

Additionally, or alternatively, integrating analog front-end circuits 120a through 120n may include amplification components 122 that enhance weak analog output signals to levels suitable for downstream processing by an analog-to-digital converter, ensuring that low magnitude computations may be accurately processed to improved signals for input to the analog-to-digital converter. In one or more embodiments, NAND flash memory matrix 110 may be organized not only into rows and columns but also into multiple independently addressable banks, thereby forming a three-dimensional structure of selectable memory planes. Each bank may comprise a subset of bitlines and wordlines, enabling localized computation and data access with reduced interconnect complexity and power consumption. In such embodiments, integrating analog front-end circuits 120a through 120n may be configured to receive analog signals originating from selected banks and to perform charge-based or current-based accumulation across time or across multiple memory locations within a given bank. It shall be recognized that accumulation may occur through current summation, charge-domain integration, time-domain integration, or voltage-domain accumulation. In addition to signal amplification, integrating analog front-end circuits 120athrough 120nmay function to filter out noise within the analog output signals from NAND flash memory matrix 110, thereby optimizing the signal-to-noise ratio for retaining the integrity of computational results.

In some implementations, the filtered and integrated analog signals from integrating analog front-end circuits 120athrough 120nmay be routed to a given analog-to-digital converter (ADC) of a plurality of ADCs 130athrough 130n, which may be electrically coupled to a given integrating analog front-end of integrating analog front-end circuits 120athrough 120n. As discussed in more detail below, the given ADC may be configured to convert the analog signals output from the given analog front-end circuit into digital output signals and/or values thereby facilitating the transition from analog processing within NAND flash memory matrix 110 to digital signal handling stages. The a given ADC may comprise a successive approximation ADC, flash ADC, pipeline ADC, sigma-delta ADC, or time-based ADC.

Additionally, or alternatively, integrating analog front-end circuits 120athrough 120nmay function to accommodate both two-dimensional (2D) and three-dimensional (3D) configurations of NAND flash memory matrix 110. In 2D configurations, integrating analog front-end circuits 120athrough 120ninterface directly with a single plane of bitlines and wordlines, efficiently handling computations across flat grid arrangements. In 3D configurations, integrating analog front-end circuits 120athrough 120n manage analog signals from vertically stacked planes of bitlines and wordlines.

In one or more embodiments, integrating analog front-end circuits 120athrough 120nmay be configured with a differential connection to a pair of bitlines within NAND flash memory matrix 110. Accordingly, the differential configuration of a given integrating analog front-end circuit along a given pair of bitlines facilitates the handling of both positive and negative weights in matrix computations, a capability that may be required for performing summation, subtraction or similar operations with resulting products of matrix multiplications.

In one or more embodiments, the differential connection of integrating analog front-end circuits 120a through 120nto NAND flash memory matrix 110 preferably includes pairing specific bitlines, such as bitlines 111a and 111b, where each bitline may be designated to carry signals representing either positive or negative analog signals. By employing a differential connection to a given analog front-end circuit, integrating analog front-end circuits 120athrough 120n may function to differentiate between and process positive and negative analog weights during the execution of dot products or matrix multiplication tasks. Accordingly, in such embodiments, the differential connection may function to allow for dynamic arithmetic operations directly at the signal integration level.

Additionally, or alternatively, the system may employ a time-multiplexed signaling scheme in which positive and negative components of the analog input are applied sequentially to the same bitline or select gate input over distinct time windows. In such embodiments, the integrating analog front-end circuits 120athrough 120naccumulate charge corresponding to the positive component during a first time interval, followed by accumulation of charge corresponding to the negative component during a second time interval. The front-end circuit then computes the effective differential result by subtracting the integrated negative contribution from the integrated positive contribution. The time-multiplexed approach provides a functionally equivalent alternative to hardware-based differential signal paths and supports signed arithmetic without requiring duplicate physical signal lines, thus offering design flexibility for compact or resource-constrained analog compute architectures.

In some implementations, the differential connection to pairs of bitlines allows integrating analog front-end circuits 120athrough 120nto process both real-time signal variations and fixed patterns of data within NAND flash memory matrix 110. As a result, integrating analog front-end circuits 120athrough 120nenables arithmetic functions needed for diverse artificial intelligence applications, such as convolutional neural networks where precise calculation of weighted sums may be required.

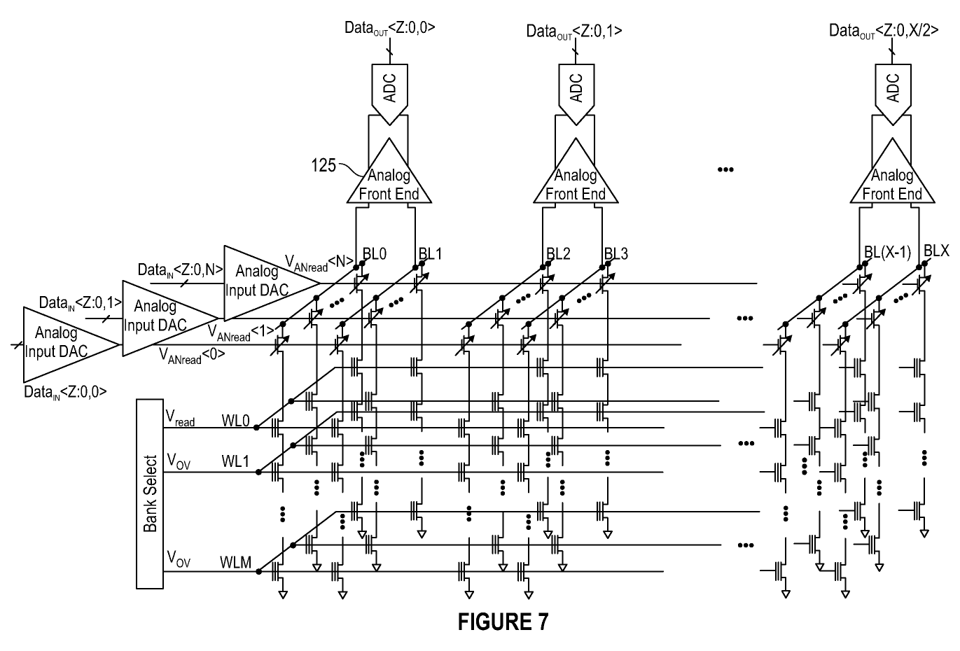

As shown by way of example in FIG. 7, in a variation, system 100 may function to implement analog front-end circuit 125 that may be non-integrating. In one or more embodiments, analog front-end circuit 125 may be designed to interface with NAND flash memory matrix 110, specifically configured for processing of analog input voltages applied through select gates 113athrough 113n. In such embodiments, analog front-end circuit 125 may be configured without typically capacitors or energy storage devices used for integrating energy values over time and may be adapted to different operational requirements by integrating a flexible ADC (analog-to-digital converter) design that may function to transition between standard integrating functionalities and acting as a direct current input ADC. The adaptability of analog front-end circuit 125, when analog input voltages may be directly used at select gates 113athrough 113n, leverages a capability of the analog front-end circuit 125 to process current directly resulting from the analog inputs at the select gates 113athrough 113nwithout necessitating integration over time.

### 1.30 Analog-to-Digital Converters

In one or more embodiments, one or more analog-to-digital converters (ADCs) 130a through 130n may be operably coupled to integrating analog front-end circuits 120athrough 120n, as shown by way of example in FIG. 4, facilitating the transition from analog to digital signal processing within NAND flash memory system 110. ADCs 130athrough 130nmay be configured to receive processed analog signals from analog front-end circuits 130athrough 130n, translating the processed analog signals into discrete digital outputs for further computation. Each ADC of ADCs 130athrough 130nmay function to operate in conjunction with an associated analog front-end circuit of integrating analog front-end circuits 120athrough 120nto perform digital quantification of analog signals, ensuring accurate digital representation of matrix multiplication and analog signal summation results. ADCs 130athrough 130nmay be optimized for high-speed, high-precision conversion, allowing rapid processing of large-scale neural network computations embedded within NAND flash memory matrix 110.

As described in U.S. Patent No. 10,389,375, which is incorporated herein by reference in its entirety, integrating analog front-end circuits 120athrough 120btogether with ADCs 130athrough 130nmay function as a readout circuit that may function to determine, from a weighted sum current signal, a digital output signal or code. In such embodiments, readout circuitry preferably includes a differential current circuit, a common-mode current circuit, and a comparator circuit operating in concert to determine a weighted sum calculation result for a given set of analog inputs into NAND flash memory matrix 110.

### 1.40 Pulse Width Modulator

In one or more embodiments, pulse width modulator 140 may be operably integrated with NAND flash memory matrix 110 for modulating analog input signals that control the operations of the plurality of select gates 113athrough 113n of NAND flash memory matrix 110. Pulse width modulator 140 modulates analog gate voltages into pulse width modulated signals that may be used during in-memory computations, such as matrix multiplies. Pulse width modulator 140 preferably functions to provide precise modulation of pulse width in digital input signals allowing for control over the duration and intensity of the analog signals (e.g., gate voltages) used for driving select gates 113athrough 113nand managing other timing-dependent processes. Accordingly, in such embodiments, the analog input signals determine the temporal characteristics of the input applied to each memory cell of NAND flash memory matrix 110, directly affecting the duration for which each stored weight of a given memory cell of NAND flash memory matrix 110 may be actively integrated by a given analog front-end circuit of analog front-end circuits 120athrough 120n.

Additionally, or alternatively, pulse width modulator 140 may function to operate by converting continuous analog input signals, defined by digital data input values, into modulated pulses with variable widths. In such embodiments, the width of each pulse corresponds to an amplitude of the analog input, enabling control over the timing of current flow through select gates 113athrough 113n. The modulation by pulse width modulator 140, in such embodiments, may function to ensure that electrical values produced along given layers, or combinations of bitlines 111athrough 111nand wordlines 112athrough 112n, may be accurately processed for the time durations for matrix multiplication tasks within NAND flash memory matrix 110.

In one implementation, pulse width modulator 140 comprises a microcontroller or a dedicated analog signal processor equipped with a digital-to-analog conversion circuit.

### 1.50 Wordline Bank Select

In one or more embodiments, wordline bank select 150 may be configured to facilitate the activation and management of wordlines 112a through 112nwithin NAND flash memory matrix 110. Wordline bank select 150 preferably functions to regulate access to memory cells of NAND flash memory matrix 110 during read, write, and computational operations, ensuring that the relevant of wordlines 112a through 112nmay be engaged at any given time to enhance system efficiency and performance.

In one or more embodiments, the term “bank,” as used herein, may refer to a grouping or subset of conductive lines, memory cells, select gates, or other circuit elements that may be activated, addressed, controlled, or processed collectively during a given operation. A bank may comprise a physically contiguous grouping of elements or a logically defined grouping formed through multiplexing, switching, or routing circuitry. A bank may be statically defined during design or fabrication, or dynamically configurable during operation through control signals. The term “bank” is not limited to fixed hardware partitions and may include any selectable subset of elements within NAND flash memory matrix 110 that may participate collectively in an analog computation, read operation, or write operation.

Additionally, or alternatively, wordline bank select 150 operates by receiving control signals that dictate which wordlines of wordlines 112a through 112nshould be activated based on computational requirements or data access commands. Upon receiving one or more control signals, wordline bank select 150 selects and energizes specific wordlines of wordlines 112a through 112n, enabling targeted interaction with the corresponding weights of memory cells within NAND flash memory matrix 110.

In some embodiments, wordline bank select 150 may be implemented using a series of latching circuits or demultiplexers that facilitate rapid switching between wordlines of wordlines 112athrough 112n. In such embodiments, the components of wordline bank select 150 allow for quick response to control signals, providing agility that may be required for complex computational tasks. Additionally, wordline bank select 150 may include buffering components to stabilize the wordline signals, minimizing latency and fluctuation during activation.

Additionally, the strategic and/or intelligent operation of wordline bank select 150 supports power optimization by ensuring that only subject sections of NAND flash memory matrix 110 may be active during specific operations, thus reducing overall power consumption. This efficiency may be technically beneficial in systems that handle extensive data processing and memory-intensive applications such as large-scale neural network inference (e.g., large language models).

Additionally, or alternatively, integration of wordline bank select 150 enables scalability within an architecture of NAND flash memory matrix 110, allowing for expansion and adaptation to different application requirements.

### 1.55 Select Gate Bank Select

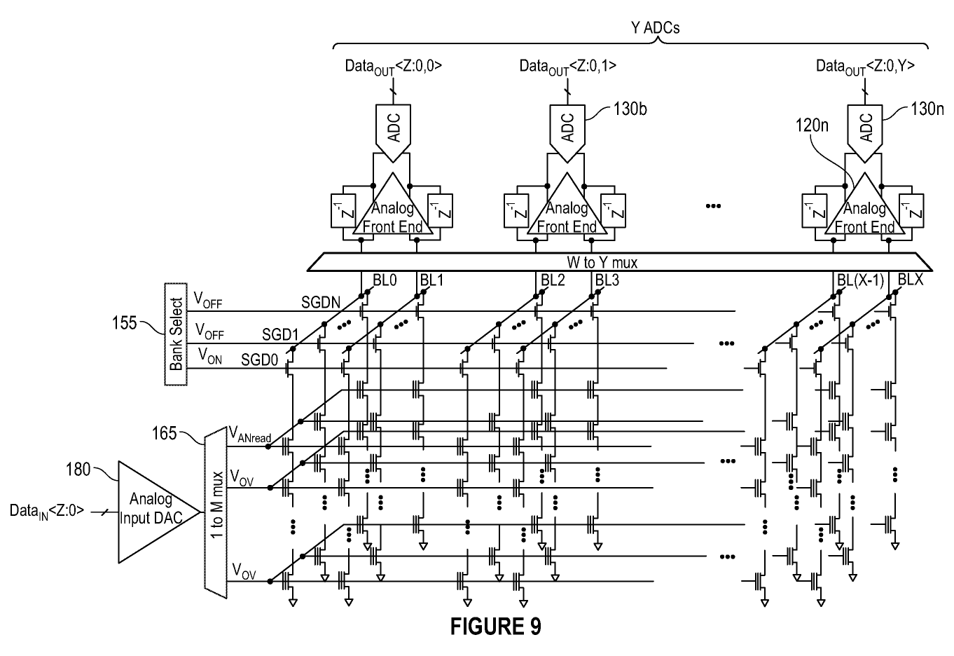

In one implementation, as shown in FIG. 9, system 100 may function to implement a select gate bank select 155. In one or more embodiments, select gate bank select 155 may be configured to manage and control the activation of select gates 113athrough 113nwithin NAND flash memory matrix 110. Select gate bank select 155 may function to coordinate access to memory cells within NAND flash memory matrix 110, facilitating precise select gate activation during read, write, and computational operations.

Additionally, or alternatively, select gate bank select 155 preferably operates by receiving control signals that specify which select gates select gates 113athrough 113nshould be engaged, based on operational requirements or data processing demands. Upon receiving the control signals, select gate bank select 155 initiates the activation of designated select gates, allowing for targeted signal interaction with corresponding rows of devices. In such embodiments, the targeted gating enables in-memory computations, such as matrix multiplications between analog input vectors and an analog weight matrices.

In some embodiments, select gate bank select 155 employs an array of switching circuits or multiplexers to enable swift transitions between select gates select gates 113athrough 113n. Moreover, select gate bank select 155 may incorporate buffering elements to maintain signal stability during the activation process, thereby minimizing potential disturbances and ensuring consistent operation.

In one or more embodiments, while select gate bank select 155 manages grouping of select gates 113athrough 113n, complementary grouping functionality may be provided for bitlines 111athrough 111nthrough bitline multiplexer 160, enabling formation of bitline banks in a manner analogous to select gate banks and wordline banks. The coordinated control of select gate banks, wordline banks, and bitline banks may enable multi-dimensional partitioning of NAND flash memory matrix 110 for scalable analog computation.

### 1.60 Bitline Multiplexer

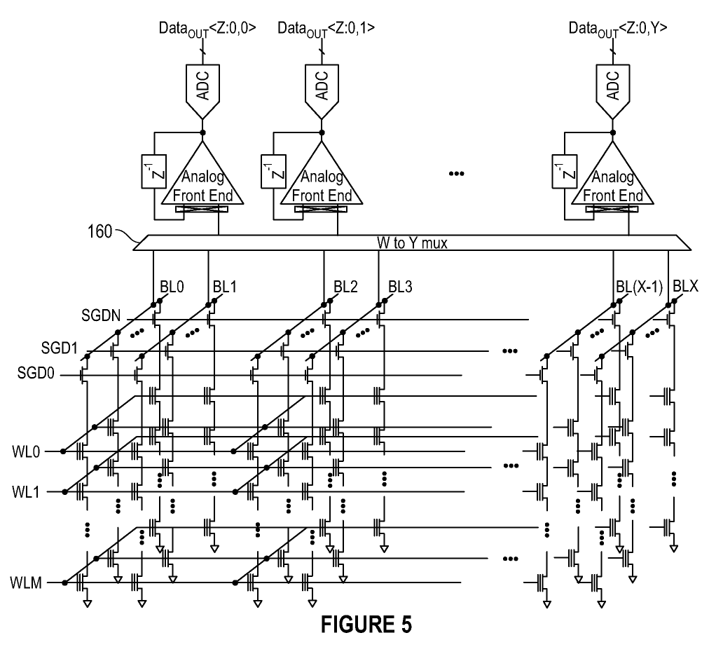

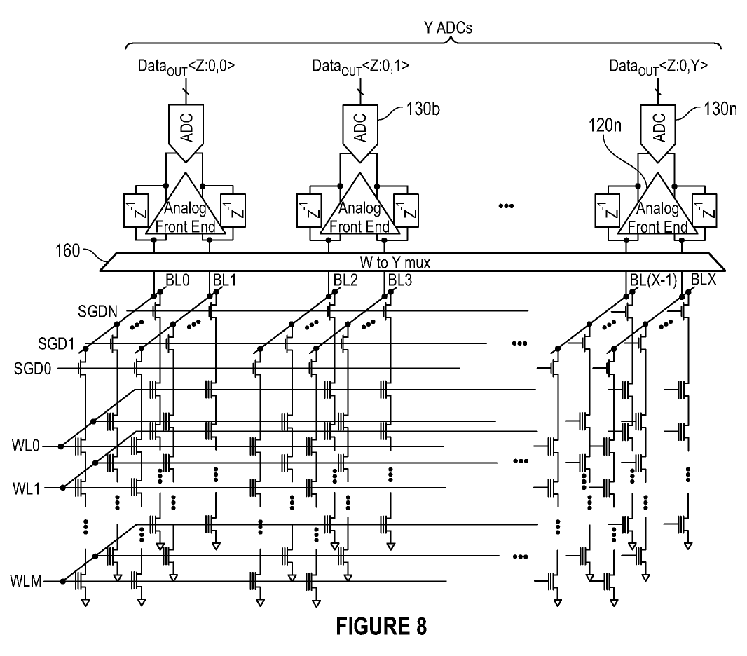

In one or more embodiments, bitline multiplexer 160 may be configured to facilitate the efficient routing and integration of signals across bitlines 111a through 111nwithin NAND flash memory matrix 110, as shown by way of example in FIGS. 5, and 8. Bitline multiplexer 160 may function to manage data flow and optimize communication pathways during read, write, and computation operations.

In one or more embodiments, bitline multiplexer 160 may be configured not only to selectively route individual bitlines 111athrough 111n, but also to group a subset of the plurality of bitlines 111athrough 111ninto one or more bitline banks. Each bitline bank may comprise a selected grouping of bitlines that may be collectively coupled to a common analog front-end circuit of integrating analog front-end circuits 120athrough 120n. The formation of bitline banks may enable selective activation, readout, or integration of defined subsets of memory cells within NAND flash memory matrix 110 during analog computation operations.

In one or more embodiments, the grouping of bitlines into banks via bitline multiplexer 160 may function similarly to the grouping of wordlines by wordline bank select 150 and the grouping of select gates by select gate bank select 155. The bitline banks may be dynamically configurable based on control signals received from a control circuit, allowing adaptation to varying computational requirements, neural network layer dimensions, or matrix partitioning schemes.

In some embodiments, bitline multiplexer 160 may function to operate by selectively connecting one or more bitlines of the plurality of bitlines 111athrough 111nto a common output or to a shared integration node, thereby forming a configurable bitline bank that may participate collectively in analog integration. The term “integration node” may refer to a node within an analog front-end circuit at which electrical contributions from multiple memory cells are accumulated through charge integration or current summation.

Additionally, or alternatively, bitline multiplexer 160 may function to operate by selectively connecting and channeling electrical signals from one or more bitlines to a common output, such as to a given analog front-end circuit of integrating analog front-end circuits 120athrough 120nbased on operational requirements or specific data processing commands. The selective routing by bitline multiplexer 160 organizes data paths within NAND flash memory matrix 110 thereby ensuring that signal processing may be streamlined, such as during complex in-memory computations that may be required for analog matrix multiplications.

### 1.65 Wordline Multiplexer

In one implementation, as shown in FIG. 9, system 100 may implement wordline multiplexer 165. In one or more embodiments, wordline multiplexer 165 may be configured to enable the selection and routing of analog signals across wordlines 112athrough 112nwithin NAND flash memory matrix 110. Wordline multiplexer 165 may function to optimize data path efficiency within NAND flash memory matrix 110 thereby enhancing the transition of signals during read, write, and computational processes through selective wordlines.

Additionally, or alternatively, wordline multiplexer 165 may function to operate by selectively coupling one or more wordlines of wordlines 112athrough 112b to a common control or data path, based on incoming control signals or specific operational instructions for a given computation operation.

In some embodiments, wordline multiplexer 165 may be implemented using a combination of transistors or other multiplexing circuitry that allows for dynamic selection of particular wordlines of wordlines 112athrough 112n. The components of wordline multiplexer 165 may function to enable efficient and flexible engagement of select data paths within NAND flash memory matrix 110. Additionally, or alternatively, wordline multiplexer 165 may include buffering and amplification mechanisms to preserve signal clarity and minimize transition delays.

### 1.70 Analog Input DACs

In one or more embodiments, as shown by way of example in FIG. 6, analog input digital-to-analog converters (DACs) 170 may be configured to receive and convert digital input signals into analog signals computation operations within NAND flash memory matrix 110. In one or more embodiments, analog input DACs 170 may be configured to apply analog voltages to the one or more of the plurality of select gates 113athrough 113nof NAND flash memory matrix 110. Analog input DACs 170 may function to modulate the resistance of the memory cells of NAND flash memory matrix 110, facilitating control over the gate voltages of the plurality of select gates 113athrough 113nto enable in-memory computations.

Additionally, or alternatively, analog input DACs 170 may function to provide shared analog voltages used as reference inputs during the programming and verification of threshold voltages of memory cells within NAND flash memory matrix 110. In one or more embodiments, compensation for manufacturing mismatches in the memory cells or analog circuitry is achieved by adjusting the programmed threshold voltage levels of the memory cells of NAND flash memory matrix 110 during calibration, such that the resulting cell currents align with expected values when driven by the common DAC output voltages. In such embodiments, the DAC voltages provided via input DACs 170 are fixed across multiple memory cells, and the programming algorithm accounts for both cell-to-cell variation and DAC variation by selectively tuning the memory cell threshold levels rather than tuning individual DAC outputs per memory cell.

In some implementations, the modulation by analog input DACs 170 ensures that the respective analog voltage applied to the plurality of select gates 113athrough 113n addresses variations caused by inherent manufacturing discrepancies. Analog input DACs 170 adjust the characteristics of the memory cells to deliver consistent performance, similar to the method used in NOR flash systems where a precise number of electrons may be placed on the floating gate to neutralize mismatch effects.

In some implementations, the modulation by analog input DACs 170 ensures that the respective analog voltage applied to the plurality of select gates 113athrough 113naddresses variations caused by inherent manufacturing discrepancies. Analog input DACs 170 adjust the characteristics of the memory cells to deliver consistent performance, similar to the method used in NOR flash systems where a precise number of electrons may be placed on the floating gate to neutralize mismatch effects.

Moreover, unlike programmed transistors whose threshold voltages are explicitly adjusted during setup to compensate for device variability, the transistors controlled by analog input DACs 170 may exhibit natural mismatches due to manufacturing process variations. Analog input DACs 170, however, are configured to deliver fixed or shared analog voltage levels across groups of memory cells or select gates within NAND flash memory matrix 110. In one or more embodiments, precision in matrix multiplications and analog in-memory computations is achieved not by dynamically tuning DAC outputs per memory cell, but by programming the threshold voltage of individual memory cells such that the resulting current response under a fixed DAC input matches a target profile. During calibration or verification phases, common analog voltages generated by analog input DACs 170 are applied while a memory programming algorithm iteratively tunes the threshold voltage of each cell to account for both memory cell variability and DAC non-idealities. In this manner, the architecture achieves the precise control required for reliable analog computation while simplifying the design of DAC circuitry.

### 1.80 Analog Input DAC

In or more embodiments, analog input digital-to-analog converter (DAC) 180 operates in conjunction with wordline multiplexer 165 to manage the distribution of analog inputs across wordlines 112a through 112nwithin NAND flash memory matrix 110. Analog input DAC 180 may function to convert digital input signals into precise analog voltages applied to selected wordlines of wordlines 112athrough 112n, thereby controlling the gate voltage of flash transistors associated with each layer.

Additionally, or alternatively analog input DAC 180 may function by cycling through various select gate banks based on digital input signals, enabling a configurable approach to integrating electrical values on analog front-end circuits 120a through 120n. The operation of the wordline multiplexer 165 by analog input DAC 180 may function to ensure that one or more selected wordlines of NAND flash memory matrix 110 receive an intended analog input voltage, while other wordlines may be maintained at an overdrive voltage V_{OV}.

### 1.9.1 System-Level Integration and Packaging Architectures

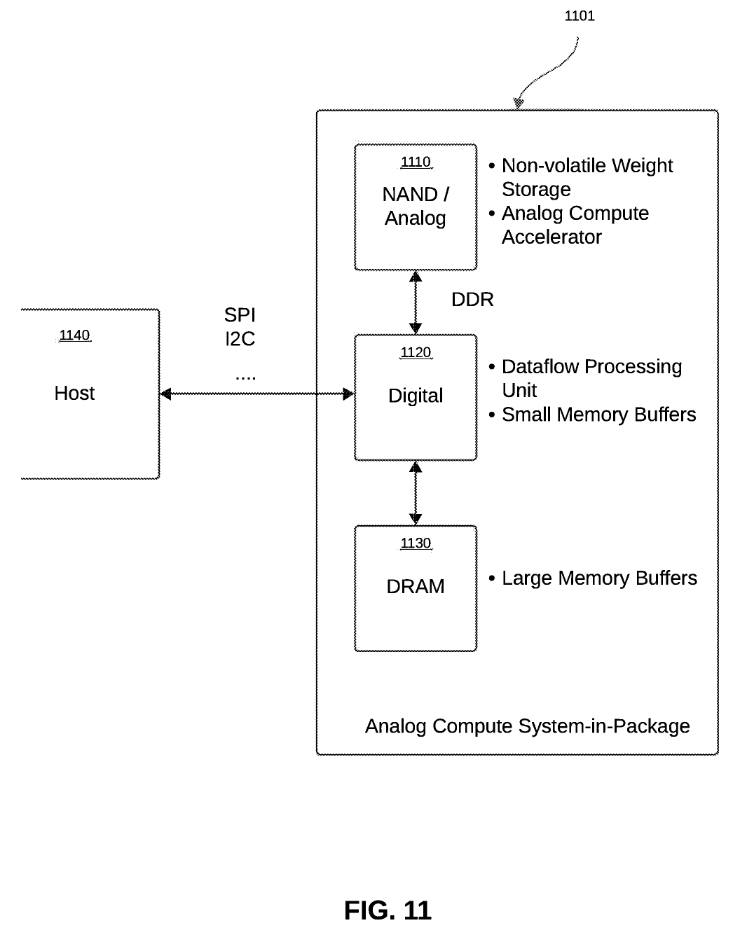

In one or more embodiments, system 100 may be implemented as part of a multi-die integrated architecture that electrically and physically integrates a NAND-based analog compute die with one or more digital processing dies and one or more memory buffer dies. As illustrated by way of example in FIG. 11, an analog compute system 1101 may include a host interface 1140, a digital processing unit 1120, a dynamic random-access memory (DRAM) buffer 1130, and a NAND/analog compute accelerator 1110 that may cooperate to perform artificial intelligence inference and other computationally intensive tasks. As used herein, the term “analog compute accelerator” may refer to a circuit architecture configured to perform computational operations using analog electrical quantities, including currents, voltages, charges, or time-domain signals, within memory arrays or associated readout circuitry.

In one or more embodiments, the host interface 1140 may be configured to communicate with the digital processing unit 1120 using one or more serial or parallel communication protocols, including Serial Peripheral Interface (SPI), Inter-Integrated Circuit (I²C), or other suitable control or configuration interfaces. The host interface 1140 may provide configuration parameters, model selection commands, neural network layer instructions, and digital input activation values to the digital processing unit 1120. Bandwidth requirements between the host interface 1140 and the digital processing unit 1120 may be lower than bandwidth requirements between the digital processing unit and the NAND/analog compute accelerator.

In one or more embodiments, the digital processing unit 1120 may include control logic, scheduling circuitry, dataflow management circuitry, and local memory buffers. The digital processing unit 1120 may function to coordinate activation of NAND flash memory matrix 110, control pulse width modulation timing, manage bank select circuitry, sequence analog-to-digital conversion operations, and manage intermediate digital results. The digital processing unit 1120 may communicate with the NAND/analog compute accelerator 1110 using a high-speed digital interface, which may include a double data rate (DDR) interface or another high-throughput communication link. The high-speed interface may transport digital outputs generated by analog-to-digital converters 130a–130n as well as configuration and control signals directed toward NAND flash memory matrix 110 and associated analog front-end circuitry.

In one or more embodiments, the NAND/analog compute accelerator 1110 may include NAND flash memory matrix 110, integrating analog front-end circuits 120a–120n, analog-to-digital converters 130a–130n, and associated bank select and multiplexing circuitry. The NAND/analog compute accelerator 1110 may function to store non-volatile neural network weights and perform in-memory analog computations, including dot products and matrix multiplications, using stored weight values and applied input activations. Accumulated analog signals may be converted into digital output values and transmitted to the digital processing unit for further processing or routing.

In some embodiments, a portion of digital logic may be integrated on the NAND/analog compute accelerator 1110 to perform post-conversion processing operations including activation functions, thresholding, sparsity detection, compression, or partial accumulation. In some embodiments, sparse input activations may selectively activate only a subset of select gates or wordlines, reducing power consumption during inference. Localized digital processing on the NAND/analog compute accelerator 1110 may reduce inter-die bandwidth requirements and may reduce power consumption associated with high-speed data transmission.

In one or more embodiments, the DRAM buffer 1130 may provide large-capacity temporary storage for input activation vectors, intermediate neural network layer outputs, partial accumulation results, and configuration data. The DRAM buffer 1130 may be electrically coupled to the digital processing unit 1120 and may also be electrically coupled to the NAND/analog compute accelerator 1110. Selected digital signals may pass through the DRAM buffer 1130 without storage, while other signals may be temporarily staged within the DRAM buffer 1130 based on computational scheduling requirements.

Dataflow within the multi-die architecture may proceed by receiving digital input values from the host interface 1140, staging and conditioning digital input values within the digital processing unit 1120, transmitting digital input values to the NAND/analog compute accelerator 1110, performing in-memory analog computation within NAND flash memory matrix 110, integrating analog current outputs using integrating analog front-end circuits 120a–120n, converting accumulated analog values to digital output values using analog-to-digital converters 130a–130n, transmitting digital output values to the digital processing unit 1120, optionally performing additional digital conditioning, and transmitting results to the host interface 1140 or storing intermediate values within the DRAM buffer 1130.

### 1.9.2 System-in-Pack via Micro-Bump Architecture

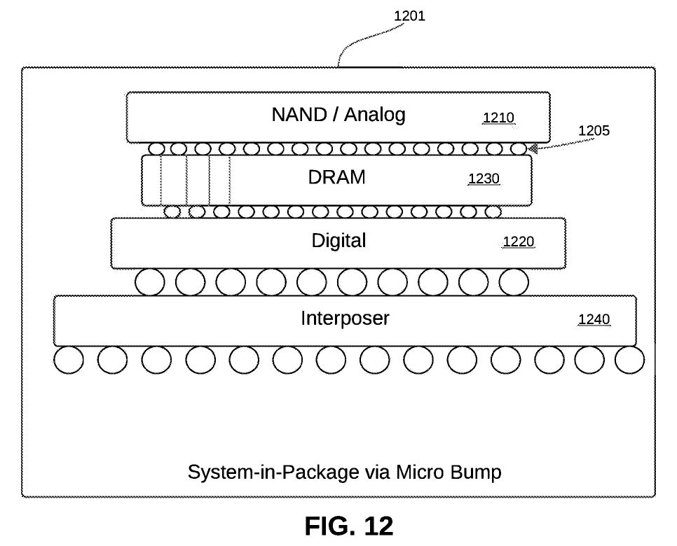

As illustrated by way of example in FIG. 12, an analog compute system may be implemented using a chip-level system-in-package architecture 1201 in which a plurality of semiconductor dies are vertically stacked and electrically coupled using fine-pitch micro-bump interconnect structures. In one or more embodiments, the system-in-package architecture 1201 may include a NAND/analog compute die 1210, a dynamic random-access memory (DRAM) die 1230, a digital processing die 1220, and an interposer substrate 1240 that provides electrical routing and mechanical support.

In one or more embodiments, the NAND/analog compute die 1210 may be positioned above the DRAM die 1230, and the DRAM die 1230 may be positioned above the digital processing die 1220. The digital processing die 1220 may be mounted to the interposer substrate 1240, which may include redistribution layers configured to distribute power, ground, clock signals, and high-speed digital signals between the stacked dies and external package contacts. Alternative vertical arrangements of the dies may be implemented based on electrical, thermal, or signal integrity considerations.

Electrical coupling between adjacent dies may be achieved using micro-bump interconnect structures 1205 that provide vertical conductive pathways. Micro-bump interconnects 1205 may include solder-based bumps, copper pillar bumps, conductive polymer interconnects, or other fine-pitch vertical conductive structures. The micro-bump interconnects 1205 may be configured to transmit high-speed digital data signals associated with outputs of analog-to-digital converters 130a–130n, clock distribution signals, configuration signals, bank select control signals, and power and ground connections. In certain embodiments, the micro-bump pitch may be selected to support wide parallel data buses between the NAND/analog compute die 1210 and the digital processing die 1220 to enable high-bandwidth communication.

In one or more embodiments, the DRAM die 1230 may provide temporary storage for input activation vectors, intermediate neural network layer outputs, and partial accumulation results. Selected digital signals transmitted between the NAND/analog compute die 1210 and the digital processing die 1220 may pass through routing structures within the DRAM die 1230 without storage, while other signals may be buffered based on system requirements. The DRAM die 1230 may include internal metallization layers that enable direct signal routing between vertically stacked dies.

The digital processing die 1220 may include dataflow scheduling logic, memory controllers, high-speed input/output drivers, serializer/deserializer circuits, and control circuitry configured to manage operation of NAND flash memory matrix 110 and associated analog front-end circuitry. In one or more embodiments, a limited amount of digital post-processing logic may also be integrated on the NAND/analog compute die 1210 to perform activation functions, thresholding operations, sparsity filtering, or output compression prior to transmission to the digital processing die 1220, thereby reducing inter-die data bandwidth requirements.

Positioning of the NAND/analog compute die 1210 at an upper location within the stack may reduce exposure of integrating analog front-end circuits 120a–120n to digital switching noise generated within the digital processing die 1220. Physical separation between analog circuitry and high-speed digital switching circuitry may reduce substrate noise injection, ground bounce, and clock coupling into sensitive integration nodes. In certain embodiments, shielding layers or ground planes may be incorporated within one or more dies to further improve analog signal integrity.

In one or more embodiments, each die within the system-in-package may be fabricated using a semiconductor process optimized for a particular function. The NAND/analog compute die 1210 may utilize a non-volatile memory fabrication process optimized for programmable threshold voltage control, the digital processing die 1220 may utilize a logic-optimized CMOS process, and the DRAM die 1230 may utilize a memory-optimized dynamic RAM process. The system-in-package architecture 1201 may therefore enable heterogeneous integration across different technology nodes while maintaining process specialization for memory, analog computation, and digital logic.

### 1.9.3 Wafer Stack Packaging with Through-Silicon Vias

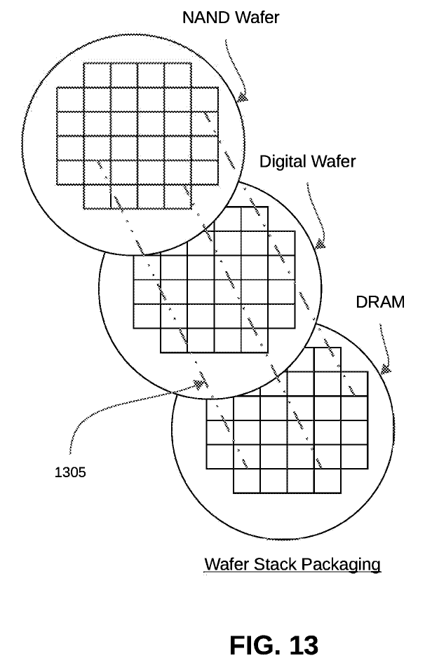

As illustrated by way of example in FIG. 13, an analog compute system may be implemented using a wafer-level stacking architecture in which multiple semiconductor wafers are vertically aligned and bonded prior to singulation into individual die packages. In one or more embodiments, the wafer-level stacked architecture may include a NAND wafer comprising a plurality of NAND/analog compute die regions, a digital logic wafer comprising a plurality of digital processing die regions, and a dynamic random-access memory (DRAM) wafer comprising a plurality of memory die regions. Each wafer may be fabricated independently and subsequently integrated through wafer-to-wafer bonding techniques.

In one or more embodiments, the plurality of wafers may be aligned using lithographic alignment marks and bonded using oxide-to-oxide bonding, copper-to-copper hybrid bonding, thermo-compression bonding, adhesive bonding, or other suitable wafer bonding processes. Following bonding, the composite wafer stack may be diced to form vertically integrated semiconductor devices in which each resulting device includes aligned regions from the NAND wafer, the digital wafer, and the DRAM wafer.

Electrical interconnection between the wafers may be achieved using through-silicon vias 1305 extending vertically through one or more semiconductor substrates. Through-silicon vias 1305 may include vertically etched conductive channels that are filled with conductive material, including copper or tungsten, and may provide electrical coupling between circuitry formed on different wafers. In one or more embodiments, through-silicon vias 1305 may electrically couple NAND flash memory matrix 110 and associated integrating analog front-end circuits 120a–120n to digital processing circuitry formed on the digital wafer. Through-silicon vias 1305 may further electrically couple the DRAM wafer to the digital wafer to enable storage and retrieval of intermediate data.

In some embodiments, through-silicon vias 1305 may carry high-speed digital data paths associated with outputs of analog-to-digital converters 130a–130n, clock distribution signals, power supply rails, reference voltages, configuration signals, and bank select control signals. Dedicated through-silicon vias 1305 may be allocated for low-noise routing of signals originating from integrating analog front-end circuits 120a–120n to preserve signal integrity during vertical transmission. In certain implementations, selected signals may pass through the DRAM wafer without storage, while other signals may be buffered within DRAM circuitry based on computational requirements.

In one or more embodiments, each wafer in the stack may be fabricated using a semiconductor process optimized for a particular functional role. The NAND wafer may utilize a non-volatile memory process optimized for programmable threshold voltage control, the digital wafer may utilize a logic-optimized CMOS process, and the DRAM wafer may utilize a memory-optimized dynamic RAM process. Wafer-level stacking may therefore enable heterogeneous integration while preserving process specialization for memory, analog computation, and digital logic.

Vertical dataflow within the wafer-level stack may proceed by performing in-memory analog computation within NAND flash memory matrix 110, integrating current outputs using integrating analog front-end circuits 120a–120n, converting accumulated analog values to digital values using analog-to-digital converters 130a–130n, and transmitting the resulting digital outputs through one or more through-silicon vias to digital processing circuitry located on the digital wafer. The digital processing circuitry may perform additional data conditioning, activation processing, buffering, or host communication functions. DRAM circuitry may provide storage for intermediate neural network layer outputs or input activation vectors, enabling staged multi-layer computation.

In one or more embodiments, the vertical ordering of the wafers may be selected to reduce coupling of digital switching noise into analog integration circuitry. Positioning the NAND/analog wafer at an upper layer of the stack may reduce substrate noise injection from high-speed digital switching activity. Shielding layers, ground planes, isolation trenches, or other noise mitigation structures may be incorporated within one or more wafers to further improve analog signal integrity. Thermal distribution considerations may also influence wafer ordering, as digital processing circuitry may generate higher switching power density relative to analog memory arrays. Thermal vias, heat spreading layers, or other thermal management structures may be incorporated to manage heat dissipation across the stacked wafer assembly.

### 1.9.4 Planar Interposer-Based Multi-Die Integration

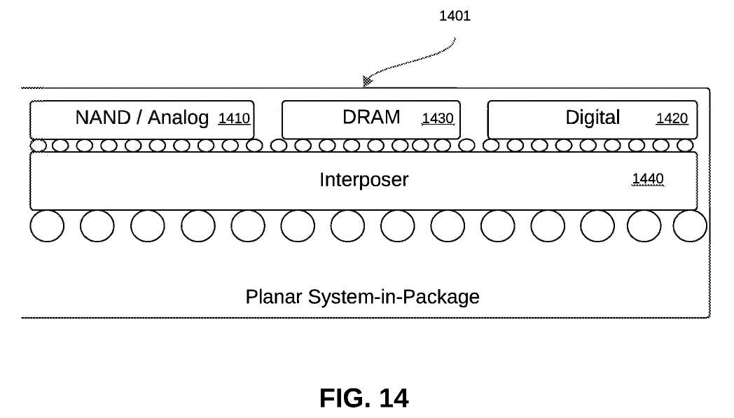

As illustrated by way of example in FIG. 14, an analog compute system may be implemented using a planar multi-die integration architecture 1401 in which a NAND/analog wafer 1410, a dynamic random-access memory (DRAM) wafer 1430, and a digital processing wafer 1420 are arranged along a same or substantially similar plane and electrically coupled through an interposer substrate 1440. In one or more embodiments, each wafer or singulated die derived from each wafer may be mounted onto the interposer substrate 1440 using micro-bumps, copper pillar interconnects, solder bumps, conductive adhesives, or other fine-pitch conductive interconnect structures positioned between the respective wafer and the interposer.

In one or more embodiments, the interposer substrate 1440 may comprise a silicon interposer, an organic interposer, a glass interposer, or a multi-layer redistribution substrate including routing layers configured to electrically couple the NAND/analog wafer 1410, the DRAM wafer 1430, and the digital processing wafer 1420. The interposer substrate 1440 may include high-density redistribution layers that enable lateral routing of high-speed digital signals, clock distribution signals, power delivery networks, reference voltages, and control signals between the wafers.

In one or more embodiments, the NAND/analog wafer 1410 may include NAND flash memory matrix 110, integrating analog front-end circuits 120a–120n, and analog-to-digital converters 130a–130n, and may be electrically coupled to the digital processing wafer 1420 through conductive pathways formed within the interposer substrate 1410. The digital processing wafer 1420 may include dataflow control logic, scheduling circuitry, memory controllers, and host interface circuitry. The DRAM wafer 1430 may provide temporary storage of input activation vectors, intermediate neural network layer outputs, partial accumulation results, and configuration data. Electrical communication between the wafers may occur laterally through routing layers within the interposer rather than vertically through through-silicon vias.

In one or more embodiments, the conductive interconnect structures positioned between each wafer and the interposer substrate 1440 may provide vertical electrical coupling into the interposer, while the interposer substrate 1440 may provide horizontal electrical routing between adjacent wafers. Such architecture may be referred to as a two-and-one-half dimensional (2.5D) integration architecture. The planar arrangement may reduce fabrication complexity associated with full three-dimensional wafer stacking while still enabling high-bandwidth communication between heterogeneous semiconductor devices.

In one or more embodiments, positioning of the NAND/analog wafer 1410 physically separated from the digital processing wafer 1420 along the plane of the interposer 1440 may reduce coupling of digital switching noise into sensitive analog integration circuitry. Dedicated routing channels within the interposer may be allocated for analog signal transmission to preserve signal integrity. Ground shielding structures, power isolation networks, and differential routing topologies may be implemented within the interposer to further mitigate noise coupling between analog and digital domains.

In one or more embodiments, each wafer may be fabricated using a semiconductor process optimized for its functional role, including a non-volatile memory fabrication process for the NAND/analog wafer 1410, a logic-optimized CMOS process for the digital processing wafer 1420, and a memory-optimized DRAM process for the DRAM wafer 1430. The planar interposer-based architecture 1401 may therefore enable heterogeneous integration while maintaining process specialization and reducing manufacturing complexity associated with wafer-to-wafer bonding.

In operation, digital input values may be received by the digital processing wafer 1410, transmitted laterally through the interposer 1440 to the NAND/analog wafer 1410, used to activate a subset of memory cells within NAND flash memory matrix 110 to perform in-memory analog computation, converted to digital output values by analog-to-digital converters 130a–130n, and transmitted laterally through the interposer 1440 back to the digital processing wafer 1420 or to the DRAM wafer 1430 for temporary storage.

In one or more embodiments, the arrangements of semiconductor devices illustrated in FIGS. 12–14 are provided as example implementations of system-in-package configurations for integrating an analog compute accelerator with supporting memory and digital processing circuitry. The particular vertical or planar ordering of the semiconductor devices shown in FIGS. 12–14 is not intended to limit the arrangement of the respective dies or wafers within the package. For example, in some embodiments a NAND/analog die may be positioned above a DRAM die and above a digital processing die as illustrated in FIG. 12, while in other embodiments the DRAM die may be positioned above the NAND/analog die, or the digital processing die may be positioned between the NAND/analog die and the DRAM die. Similarly, in wafer-level stacked embodiments, the NAND/analog wafer, DRAM wafer, and digital wafer may be arranged in any suitable ordering depending on fabrication process requirements, signal routing considerations, thermal characteristics, or system architecture constraints. In planar system-in-package embodiments, such as illustrated in FIG. 14, the relative lateral positioning of the NAND/analog die, DRAM die, and digital die on an interposer may likewise vary without departing from the scope of the present application. Accordingly, the device orderings depicted in FIGS. 12–14 are illustrative examples, and alternative permutations of the analog compute accelerator die, DRAM die, and digital processing die may be implemented while maintaining functional communication through micro-bumps, through-silicon vias, interposer routing structures, or other interconnect technologies.

### 2.Method for NAND-Based In-Memory Analog Computations

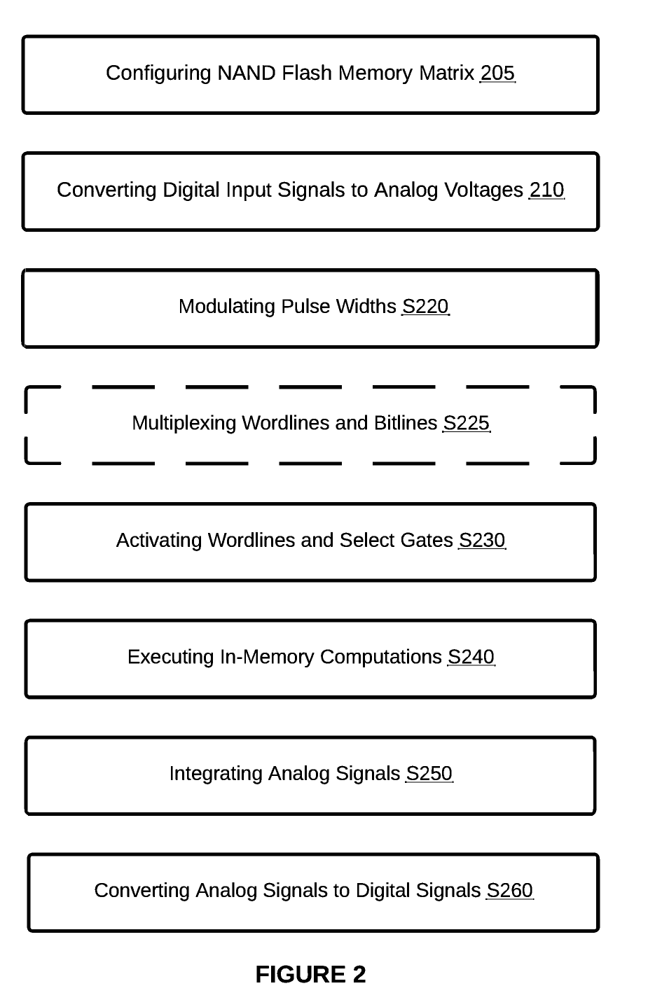

As shown in FIG. 2, the method 200 includes configuring the NAND flash memory matrix S205 to establish a structured grid of bitlines and wordlines, applying analog inputs S210 by converting digital signals into analog voltages, modulating pulse widths S220 through pulse width modulation to control signal duration, multiplexing wordlines and bitlines S225 to manage signal paths efficiently, activating wordlines and select gates S230 via bank selects to facilitate targeted computations, performing in-memory computations S240 using differential connections for matrix multiplications, integrating analog signals S250 through front-end circuits to prepare for conversion, and converting analog signals to digital signals S260 via ADCs for continued processing.

### 2.05 Configuring the NAND Flash Memory Matrix

S205, which includes configuring the NAND flash memory matrix 110, may function to establish a structured grid of bitlines 111athrough 111nand wordlines 112athrough 112nwithin NAND flash memory matrix 110, creating the framework for storing neural network weights associated with a machine learning application, such as a large language model (LLM). Each intersection formed by bitlines 111 and wordlines 112 defines a discrete memory cell capable of multi-level data storage, using distinct threshold voltage levels to enhance data capacity.

In one or more embodiments, a configuration of NAND flash memory matrix 110 may further include the arrangement of select gates 113athrough 113n, which control access to specific rows and columns of memory cells, enabling targeted activation aligned with computational requirements of a given application. In one embodiment, the architecture of the grid defined by the intersections of bitlines and wordlines enables the integration of large-scale datasets typical of language models, allowing for efficient storage and compute operations that underpin machine learning algorithms.

Additionally, or alternatively, configuring the NAND flash memory matrix 110 may include calibrating the memory cells (i.e., storage cells for neural network weights) to store programmed weights and/or biases of one or more neural network layers. In such embodiments, S205 may include a calibration process that ensures that each memory cell may be programmed to reflect the trained parameters of a given neural network (e.g., LLM) for accurate AI inferencing tasks.

In one or more embodiments, the structured grid established by S205 aligns with the overall system architecture of NAND flash memory matrix 110, accommodating enhancements such as a three-dimensional stacking (3D configuration) of memory planes. The three-dimensional architecture increases storage density, allowing for expanded computational capabilities while maintaining a compact footprint within NAND flash memory matrix 110. In such embodiment, by facilitating seamless integration with existing data handling protocols, the grid configuration of NAND flash memory matrix 110 effectively supports the execution of complex machine learning tasks.

### 2.10 Applying Analog Inputs

S210, which includes applying analog inputs, functions to convert digital input signals into analog voltages using analog input digital-to-analog converters (DACs) 170. The conversion process, in such embodiments, transforms incoming digital data into precise analog signals suitable for use within the NAND flash memory matrix 110. In use, analog voltages derived based on the digital input signals modulate the operation of select gate transistors 113athrough 113nand wordlines 112athrough 112n, allowing for effective in-memory computing and control over computational processes.

In one or more embodiments, an application of analog voltages to select gate transistors 113athrough 113nenables the modulation of gate voltages associated with each respective select gate transistors 113athrough 113n, which directly influences the resistance and conductance of memory cells within NAND flash memory matrix 110. In such embodiments, the modulation process ensures that each memory cell operates under optimal electrical conditions, enhancing both performance and reliability of memory operations. By adjusting gate voltages as needed, the system achieves finer control over data processing and signal integrity within NAND flash memory matrix 110.

In some embodiments, analog input DACs 170 may be configured to adjust the output voltages dynamically in response to varying computational requirements a given neural network application. The dynamic adjustment ensures that each select gate transistor of select gate transistors 113athrough 113nand wordline of wordlines 112athrough 112nreceives the appropriate voltage for the intended operation, whether for storing neural network weights or facilitating analog matrix multiplications within the memory structure of NAND flash memory matrix 110.

Additionally, or alternatively, the precise application of analog voltages aligns with the architecture of system 100, integrating seamlessly with multiplexing and modulation components thereof to support complex data processing tasks. By enabling targeted and efficient control over the electrical properties of memory cells, the process described in S210 enhances the overall capability and adaptability of NAND flash memory matrix 110 to meet diverse computational needs of diverse neural network applications and the like.

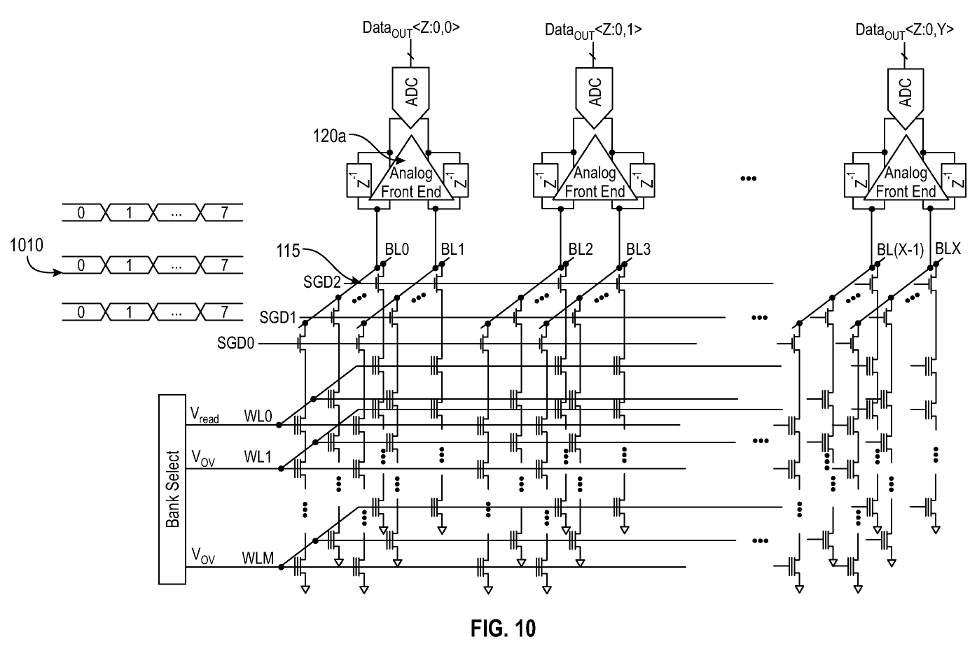

In an alternative embodiment illustrated in FIG. 10, a sequential bitwise multiplication technique may be implemented to support analog in-memory computation using NAND flash memory matrix 110. Rather than applying a complete analog input simultaneously, a set of digital input bits 1010, such as 8 bits per input, may be sequentially applied over time to select gate driver (SGD) lines 115. Each digital input bit of the set of digital input buts 1010 may correspond to a respective time interval aligned with a binary weight (e.g., 2⁰, 2¹, ..., 2⁷). Additionally, or alternatively, precision of the analog computation may be adjusted by varying the number of sequential binary input bits applied to the select gate lines, enabling programmable numerical precision without modifying the analog circuitry.

During each time interval, the active digital input bit may be applied to a target SGD line, enabling current flow from one or more selected memory cells programmed to represent neural network weights or other analog values. An integrating analog front-end circuit (AFE), such as AFE 120a, may be configured to accumulate charge generated by each current pulse. A weighted accumulation of charge may occur across all time intervals, with each bit contributing proportionally to its binary significance. Following the application of all digital input bits, the total accumulated charge may correspond to a binary-weighted analog value representative of a dot product or matrix-vector multiplication.

In one or more embodiments, the architecture illustrated in FIG. 10 may enable multiply-accumulate (MAC) operations using compact digital input signaling while preserving the advantages of analog charge-domain summation. In some embodiments, this configuration may simplify digital-to-analog conversion hardware by eliminating per-input DACs and may provide programmable precision by adjusting the number of digital input bits processed per cycle. Additionally, current-based signal flow may be accumulated without requiring distinct positive and negative bitlines, thus reducing layout complexity for large-scale analog computing arrays.

### 2.20 Modulating Pulse Widths

S220, which includes modulating pulse widths, may function to transform continuous analog input signals into pulse width modulated (PWM) signals through the implementation of pulse width modulators 140. In such embodiments, the modulation process involves adjusting the width of each pulse within the analog input signal, thereby providing precise control over both the duration and intensity of the signals used in NAND flash memory matrix 110.

In one embodiment, pulse width modulators 140 operate by receiving continuous analog input signals and applying modulation techniques to convert analog input signals into a series of PWM signals. In such embodiment, the transformation of analog input signals may be implemented for tailoring the application of power and timing during operations conducted through select gate transistors 113athrough 113nand wordlines 112athrough 112n. As such, the modulated control over the width of each pulse, controls the duration and intensity of the input signal interfacing with memory cells of NAND flash memory matrix 110, optimizing both the efficiency and the performance of in-memory compute operations.

Additionally, pulse width modulators 140 may incorporate feedback mechanisms that enable real-time adaptation to varying operational conditions and computational demands. The adaptability of the pulse width modulators 140, in such embodiments, may function to ensure that PWM signals align optimally with current system operating parameters, providing the precision for energy-efficient computing, optimized data integrity, and enhanced processing speeds.

In some implementations, pulse width modulators 140 may be supplemented by an integrated circuit topology that includes components such as digital signal processors or microcontrollers, which manage modulation algorithms and adjust the pulse widths dynamically. The setup, connected to various components of system 100, seamlessly integrates PWM signal outputs with other signal processing elements of NAND flash memory matrix 110 and/or system 100, such as multiplexers and digital-to-analog converters (DACs), thus enhancing synchronization across multiple processing layers.

In one or more embodiments, the technique described in modulating pulse widths may be integral to achieving a precise modulation strategy that underscores the capability of NAND flash memory matrix 110 to manage pulse widths effectively. By regulating signal duration and intensity through PWM techniques, the modulation process supports the execution of high-performance data processing tasks within advanced memory system applications, contributing to the robustness and adaptability of NAND flash memory matrix 110.

### 2.25 Multiplexing Wordlines and Bitlines

S225, which includes multiplexing wordlines and bitlines, may function to selectively enable signal paths within NAND flash memory matrix 110 through the use of wordline multiplexer 165 and bitline multiplexer 160. The multiplexing process organizes and routes both analog input data and control signals in a strategic manner for optimizing the management of signal paths to enhance operational efficiency of NAND flash memory matrix 110.

In a preferred embodiment, S225 may function to implement wordline multiplexer 165 and bitline multiplexer 160 in tandem, providing dynamic control over the activation of specific wordlines 112athrough 112nand bitlines 111a through 111n. The tandem configuration enables precise selection of signal paths to facilitate targeted processing tasks, such as analog matrix multiplications and neural network computations, within NAND flash memory matrix 110.

In one or more embodiments, multiplexing wordlines and bitlines S225 may include forming one or more bitline banks by grouping a subset of bitlines 111athrough 111nthrough bitline multiplexer 160, thereby enabling selective participation of memory cell subsets in an analog integration operation.

Additionally, or alternatively, wordline multiplexer 165 and bitline multiplexer 160 may be structured to accommodate real-time changes and computational demands, allowing for rapid switching between different signal paths. In one or more embodiments, each multiplexer operates by receiving control signals that dictate the operational and/or computational configuration, enabling the efficient redirection of data and control signals to their intended memory cells and analog front-end circuits of NAND flash memory matrix 110.

In one implementation, multiplexers 160 and 165 may function by leveraging a network of switchable transistors or other circuit components that provide the capability to reconFIG. signal paths of NAND flash memory matrix 110 as needed. In such implementation, employing such flexible circuitry within multiplexers 160 and 165, the multiplexing process in S225 may enable maintained data flow efficiently across the grid of bitlines and wordlines, reducing latency and enhancing data throughput.

Additionally, or alternatively, S225 may function to implement wordline multiplexer 165 and bitline multiplexer 160 to enable a scalability of NAND flash memory matrix 110, facilitating expanded processing capabilities.

### 2.30 Activating Wordlines and Select Gates

S230, which includes activating wordlines and select gates, may function to implement specific wordlines 112athrough 112nand select gates 113athrough 113nvia wordline bank select 150 and select gate bank select 155, facilitating targeted computations within memory cells of NAND flash memory matrix 110 by precisely controlling which memory paths may be active during signal processing.

In an embodiment, wordline bank select 150 receives control signals that specify which wordlines should be activated based on current computational requirements or data access commands. Upon receiving control signals, wordline bank select 150 energizes selected wordlines 112athrough 112n, enabling data flow through designated memory cells of NAND flash memory matrix 110.

Additionally, or alternatively, simultaneously, select gate bank select 155 activates a subset of select gates 113athrough 113nby processing corresponding control signals. In such embodiments, select gate bank select 155 may function to selectively manage access to memory cells along targeted rows within NAND flash memory matrix 110, ensuring that only a subset of pathways may be engaged for given in-memory computations and to enhance processing efficiency.

Additionally, or alternatively, coordinated activation provided by wordline bank select 150 and select gate bank select 155 may be for performing unique or specialized in-memory computations, such as analog matrix multiplications for a specially configured neural network application or the like. In one or more embodiments, targeted engagement optimizes energy usage, as only segments of NAND flash memory matrix 110 may be active, reducing power consumption and minimizing delays through rapid activation and deactivation cycles.

Additionally, the precise operation of wordline bank select 150 and select gate bank select 155 enables NAND flash memory matrix 110 to execute complex data processing tasks efficiently. In such embodiments, focused activation of specific memory cells and signal paths support diverse computationally intensive applications, while enabling system throughput and ensuring robust performance across varied operational scenarios.

### 2.40 Performing In-Memory Computations

S240, which includes performing in-memory computations, may function to execute matrix multiplications using analog inputs and stored weights within NAND flash memory matrix 110. The method leverages differential connections for processing both positive and negative weights, providing a framework suitable for computational tasks involved in neural network operations.

In one embodiment, step S240 employs differential input paths that connect bitlines 111a through 111n. Differential input paths receive analog signals representing both positive and negative weight values, enabling the simultaneous processing and multiplication of stored neuron weights and input activations. The configuration of differential input paths enhances the accuracy of computation results within the system.

Additionally, or alternatively, S240 uses a combination of positive and negative voltage signals along paired bitlines 111a through 111n to enable effective analog processing within the memory structure. The method supports arithmetic operations directly in the memory environment, optimizing computational throughput by avoiding the need for signals to be processed externally.

In one or more embodiments, management of differential operations involves configuring integrated circuits with analog front-end circuits 120a through 120n that integrate electrical values derived from in-memory matrix operations. In such embodiments, analog front-end circuits 120a through 120n may function to operate alongside select gate controls, such as select gate bank select 155, to align data paths and enhance sensitivity to computational inputs.

In one implementation, differential matrix multiplications may be managed by coordinating select gate bank select 155 with wordline bank select 150. In such implementation, the coordination targets specific memory pathways, allowing computations to be layered across multiple cells of NAND flash memory matrix 110. Accordingly, the coordination may enable handling large datasets, particularly in applications such as large language models, which may require extensive memory cell interaction and high calculation precision.

### 2.50 Integrating Analog Signals

S250, which includes integrating analog signals, may function to employ integrating analog front-end circuits 120athrough 120n to collect and prepare analog outputs from NAND flash memory matrix 110 for downstream processing. In a preferred embodiment, S250 may function to process electrical signals out of NAND flash memory matrix 110 ensuring that the electrical signals are suitable for conversion to digital values in subsequent processing stages.

In one embodiment, integrating analog front-end circuits 120a through 120nmay function to receive aggregated or summed analog signals generated by computations executed within NAND flash memory matrix 110. In such embodiment, integrating analog front-end circuits 120a through 120nmay function to perform the integration of incoming analog signals over a predetermined number of clock cycles, which involves summing electrical values derived from operational bitlines 111athrough 111nand wordlines 112athrough 112n.

In one or more embodiments, integrating analog front-end circuits 120a through 120 may function to sum or integrate electrical values output from a varied or random subset of memory cells of NAND flash memory matrix 110. In such embodiments, method 200 may implement in some combination the wordline select bank 150, select gate select bank 155, and/or multiplexer 160 of system 100 to selectively activate a subset of memory cells based on enabling/disabling a subset of wordlines, enabling/disabling a subset of bitlines, and/or enabling/disabling a subset of select gates of system 100. In this way, based on a configuration or computation requirements of a given neural network application many achievable combinations or subsets of memory cells may become readable while other memory cells inactive or unreadable by the one or more readout circuits of system 100. That is, while a technical advantage of the embodiments of the present application includes a capability to read multiple memory cells of NAND flash memory matrix 100 simultaneously, another technical advantage includes at least a capability of reading simultaneously only a desired subset of memory cells of NAND flash memory matrix since for given computations of a neural network application not all memory cell values may be required for producing an accurate neural network inference.

Additionally, integrating analog front-end circuits 120athrough 120nmay be designed to alleviate issues associated with signal integrity by implementing filtration mechanisms that reduce noise and unwanted signal variations. In such embodiments, the filtering and signal processing for improving signal-to-noise values of the analog signals may function to ensure that relevant and precise analog signals may be propagated forward to one or more ADCs of system 100, thereby optimizing the signal-to-noise ratio and improving the accuracy of computational outcomes.

In one implementation, integrating analog front-end circuits 120athrough 120nmay function to utilize a series of interconnected operational amplifiers and associated filtering components selected to manage combined electrical signals. In such implementation, amplification stages within integrating analog front-end circuits 120athrough 120n may further enhance the clarity of weak analog signals, aligning outputs for optimal processing by analog-to-digital converters 130athrough 130n.

### 2.60 Converting Analog to Digital Signals

S260, which includes converting analog signals to digital signals, may function to utilize analog-to-digital converters (ADCs) 130a through 130nto transform integrated analog signals into digital outputs.

In one embodiment, ADCs 130a through 130nmay function to receive integrated analog signals from integrating analog front-end circuits 120athrough 120n. In such embodiment, ADCs 130athrough 130nmay function to perform precise quantification of analog signals, translating continuous analog values into discrete digital data points.

Additionally, ADCs 130a through 130n may be configured to handle a wide dynamic range of input signals, accommodating diverse electrical values produced by matrix operations in NAND flash memory matrix 110.

In one implementation, ADCs 130athrough 130n may operate with reference signals sourced from a global or local digital-to-analog converter (DAC) arrangement, providing stable voltage references for precise conversion. In such implementation, reference signals may ensure that ADCs 130a through 130noperate within predefined thresholds, maintaining consistency and accuracy across conversion cycles.

Additionally, or alternatively, S260 may incorporate feedback mechanisms within ADCs 130a through 130n, allowing dynamic adjustments and calibration to optimize performance.

### 3. Computer-Implemented Method

Embodiments of the system and/or method can include every combination and permutation of the various system components and the various method processes, wherein one or more instances of the method and/or processes described herein can be performed asynchronously (e.g., sequentially), concurrently (e.g., in parallel), or in any other suitable order by and/or using one or more instances of the systems, elements, and/or entities described herein.

The system and methods of the preferred embodiment and variations thereof can be embodied and/or implemented at least in part as a machine configured to receive a computer-readable medium storing computer-readable instructions. The instructions are preferably executed by computer-executable components preferably integrated with the system and one or more portions of the processors and/or the controllers. The computer-readable medium can be stored on any suitable computer-readable media such as RAMs, ROMs, flash memory, EEPROMs, optical devices (CD or DVD), hard drives, floppy drives, or any suitable device. The computer-executable component is preferably a general or application specific processor, but any suitable dedicated hardware or hardware/firmware combination device can alternatively or additionally execute the instructions.

In addition, in methods described herein where one or more steps may be contingent upon one or more conditions having been met, it should be understood that the described method can be repeated in multiple repetitions so that over the course of the repetitions all the conditions upon which steps in the method may be contingent have been met in different repetitions of the method. For example, if a method requires performing a first step if a condition is satisfied, and a second step if the condition is not satisfied, then a person of ordinary skill would appreciate that the claimed steps may be repeated until the condition has been both satisfied and not satisfied, in no particular order. Thus, a method described with one or more steps that may be contingent upon one or more conditions having been met could be rewritten as a method that is repeated until each of the conditions described in the method has been met. This, however, is not required of system or computer readable medium claims where the system or computer readable medium contains instructions for performing the contingent operations based on the satisfaction of the corresponding one or more conditions and thus is capable of determining whether the contingency has or has not been satisfied without explicitly repeating steps of a method until all of the conditions upon which steps in the method are contingent have been met. A person having ordinary skill in the art would also understand that similar to a method with contingent steps, a system or computer readable storage medium can repeat the steps of a method as many times as are needed to ensure that all of the contingent steps have been performed.

Although omitted for conciseness, the preferred embodiments include every combination and permutation of the implementations of the systems and methods described herein.

As a person skilled in the art will recognize from the previous detailed description and from the figures and claims, modifications and changes can be made to the preferred embodiments of the invention without departing from the scope of this invention defined in the following claims.

We claim:

1. An integrated circuit comprising:
an analog compute accelerator comprising a plurality of conductive lines and a plurality of programmable memory elements;
a configurable selection network configured to select a subset of the plurality of conductive lines to define a selectable compute region of the analog compute accelerator;
an analog readout circuit coupled to the analog compute accelerator and configured to accumulate electrical contributions generated by the programmable memory elements in response to applied input activation signals; and
an analog-to-digital converter configured to convert an accumulated analog value produced by the analog readout circuit into a digital output value.

2. The integrated circuit of claim 1, wherein the analog compute accelerator comprises a NAND flash memory array.

3. The integrated circuit of claim 1, wherein the plurality of conductive lines comprises a plurality of bitlines arranged to intersect with a plurality of wordlines to form a grid of memory cells.

4. The integrated circuit of claim 1, wherein the plurality of conductive lines further comprises a plurality of select gate lines operably coupled to memory cells of the analog compute accelerator.

5. The integrated circuit of claim 1, wherein the plurality of conductive lines are arranged such that each conductive line of a first set intersects with a plurality of conductive lines of a second set to form programmable memory cell locations within the analog compute accelerator.

6. The integrated circuit of claim 1, wherein the configurable selection network is configured to form one or more banks comprising a selectable grouping of conductive lines.

7. The integrated circuit of claim 6, wherein the one or more banks comprise one or more of a bitline bank, a wordline bank, or a select-gate bank.

8. The integrated circuit of claim 1, wherein the configurable selection network comprises a bitline multiplexer configured to form a bitline bank coupled to a shared integration node of the analog readout circuit.

9. The integrated circuit of claim 1, wherein the analog readout circuit comprises an integrating analog front-end circuit configured to perform charge summation of analog signals produced by the programmable memory elements.

10. The integrated circuit of claim 1, further comprising a pulse width modulation circuit configured to encode input activation signals as pulse-width modulated signals applied to select-gate lines of the analog compute accelerator.

11. The integrated circuit of claim 1, wherein input activation signals are encoded as a plurality of binary input bits sequentially applied to select-gate lines of the analog compute accelerator.

12. The integrated circuit of claim 1, wherein the analog readout circuit is configured to perform signed arithmetic using differential bitlines.

13. The integrated circuit of claim 1, wherein the analog readout circuit is configured to perform signed arithmetic using time-multiplexed positive and negative input signals applied over sequential time intervals.

14. The integrated circuit of claim 1, further comprising one or more calibration circuits configured to program threshold voltages of the programmable memory elements using common digital-to-analog converter voltages.

15. The integrated circuit of claim 1, wherein the integrated circuit is implemented within a system-in-package architecture comprising a plurality of semiconductor dies coupled using micro-bump interconnect structures.

16. The integrated circuit of claim 1, wherein the integrated circuit is implemented within a wafer-level stacked architecture comprising a NAND wafer, a digital processing wafer, and a dynamic random-access memory wafer coupled using through-silicon vias.

17. A method for performing analog in-memory computation within an integrated circuit, the method comprising:
configuring an analog compute accelerator comprising a plurality of conductive lines and a plurality of programmable memory elements;
selecting, using a configurable selection network, a subset of the plurality of conductive lines to define a selectable compute region of the analog compute accelerator;
applying input activation signals to the selectable compute region;
generating electrical contributions corresponding to stored weight values of the programmable memory elements and the applied input activation signals;
accumulating the electrical contributions using an analog readout circuit to produce an accumulated analog value representing a weighted sum associated with an analog computation operation; and
converting the accumulated analog value into a digital output value using an analog-to-digital converter.

18. The method of claim 17, wherein selecting the subset of the plurality of conductive lines comprises forming a bank comprising a selectable grouping of the plurality of conductive lines.

19. An integrated circuit comprising:
a NAND flash memory matrix comprising:
(i) a plurality of bitlines and a plurality of wordlines forming a grid of memory cells; and
(ii) a plurality of select gate devices operably coupled to the memory cells;
a pulse width modulation circuit configured to generate a plurality of pulse-width modulated signals based on digital input values, each pulse-width modulated signal having a width corresponding to a respective amplitude of the digital input value;
a plurality of analog input driver circuits configured to apply the pulse-width modulated signals to one or more select gate devices of the NAND flash memory matrix;
one or more analog front-end circuits coupled to the NAND flash memory matrix, each analog front-end circuit configured to:
(i) receive analog output signals from a subset of the memory cells activated by the pulse-width modulated signals; and
(ii) integrate the analog output signals over a defined integration window to generate an accumulated analog signal representing a weighted summation of stored values in the subset;
one or more analog-to-digital converters configured to convert the accumulated analog signal into a digital output value; and
a control circuit configured to:
(i) sequentially apply a plurality of binary input bits to the select gate devices; and
(ii) in response to the sequential application of the binary input bits, direct the analog front-end circuit to perform a binary-weighted summation by accumulating charge corresponding to each bit of the plurality of binary input bits.

20. The integrated circuit of claim 19, wherein:
the control circuit is further configured to apply the plurality of binary input bits to the select gate devices during respective sequential time intervals corresponding to binary weight values, and
the analog front-end circuit accumulates charge generated during each respective time interval such that the accumulated analog signal represents a binary-weighted sum corresponding to a multiply-accumulate operation between the plurality of binary input bits and stored values of the memory cells.
